(19) United States
(12) Patent Application Publication
(10) Pub. No.: US 2025/0221207 A1
(43) Pub. Date: Jul. 3, 2025

(54) DISPLAY APPARATUS

(71) Applicant: LG Display Co., Ltd., Seoul (KR)

(72) Inventor: DongHun JUNG, Paju-si (KR)

(21) Appl. No.: 18/943,240

(22) Filed: Nov. 11, 2024

(30) Foreign Application Priority Data
Dec. 28, 2023 (KR) 10-2023-0193791

(51) Int. Cl. H10K 59/131

(52) U.S. Cl. CPC H10K 59/131

(57) ABSTRACT

The present disclosure provides a display apparatus that includes a substrate in which an active area including a plurality of subpixels and a non-active area located outside of the active area and including a pad area are defined, at least one pad disposed in the pad area, at least one data line disposed in the active area and extending in a column direction, at least one horizontal link line electrically connected to the at least one data line and extending in a row direction, at least one vertical link line electrically interconnecting the at least one horizontal link line and the at least one pad and extending in the column direction, at least one horizontal metal pattern spaced apart from the at least one horizontal link line and extending in the row direction, at least one vertical metal pattern spaced apart from the at least one vertical link line and extending in the column direction, a first area including at least one first connection hole in which the at least one data line and the at least one horizontal metal pattern are electrically connected, a second area including at least one first dummy connection hole disposed in an area where each of the at least one data line and the at least one vertical metal pattern overlaps with the at least one horizontal link line, and a third area including at least one second dummy connection hole disposed in an area where the at least one vertical link line and the at least one horizontal metal pattern overlap with each other, and that has a bezel reduction data link structure capable of correcting display artifacts such as some image display defects perceived as patterns.

### CROSS-REFERENCE TO RELATED APPLICATION

This application claims the priority benefit of Republic of Korea Patent Application No. 10-2023-0193791, filed on Dec. 28, 2023, in the Korean Intellectual Property Office, which is incorporated herein by reference for all purposes as if fully set forth herein.

### BACKGROUND

### Technical Field

The present disclosure relates to a display apparatus, and more specifically, to a display apparatus including a data link structure.

### Description of the Related Art

A display apparatus may include an active area configured to allow an image to be displayed and a non-active area in which an image is not displayed. In order for the display apparatus to perform various functionalities such as displaying an image, sensing a touch event, and the like, various structures, circuits, lines, and the like may be disposed in the non-active area (which may also be referred to as “bezel”) of a display panel. To meet market demands for a large active area, it would be desirable to reduce the bezel of a display panel. However, since various control elements of the display panel are located in the non-active area, it is not easy to reduce the bezel of a display panel. In particular, since link lines for delivering data signals to data lines may be disposed in the non-active area of a display panel, it has become a significant challenge to reduce the bezel of the display panel.

### BRIEF SUMMARY

One or more aspects of the present disclosure may provide a display apparatus with a data link structure capable of reducing the bezel of a display panel.

One or more aspects of the present disclosure may provide a display apparatus with a bezel reduction data link structure capable of improving image quality.

One or more aspects of the present disclosure may provide a display apparatus with a bezel reduction data link structure capable of improving the performance of transmitting a common driving voltage.

One or more aspects of the present disclosure may provide a display apparatus with a bezel reduction data link structure capable of correcting display artifacts such as some image display defects perceived as patterns.

According to one or more example embodiments of the present disclosure, a display apparatus can be provided that includes a substrate in which an active area including a plurality of subpixels and a non-active area located outside of the active area and comprising a pad area are defined, at least one pad disposed in the pad area, at least one data line disposed in the active area and extending in a column direction, at least one horizontal link line electrically connected to the at least one data line and extending in a row direction, at least one vertical link line electrically interconnecting the at least one horizontal link line and the at least one pad and extending in the column direction, at least one horizontal metal pattern spaced apart from the at least one horizontal link line and extending in the row direction, at least one vertical metal pattern spaced apart from the at least one vertical link line and extending in the column direction, a first area including at least one first connection hole through which the at least one data line and the at least one horizontal metal pattern are electrically interconnected, a second area including at least on first dummy connection hole in an area in which each of the at least one data line and the at least one vertical metal pattern overlaps with the at least one horizontal link line, and a third area including at least one second dummy connection hole in an area in which the at least one vertical link line and the at least one horizontal metal pattern overlap with each other.

In one or more aspects, the display apparatus may further include at least one second connection hole through which the at least one data line and the at least one horizontal link line are electrically interconnected, and at least one third connection hole through which the at least one horizontal link line and the at least one vertical link line are electrically interconnected. The at least one second connection hole may be disposed in a first inclined direction relative to a horizontal or vertical direction, and the at least one third connection hole may be disposed in a second inclined direction different from the first inclined direction.

In one or more aspects, a boundary between the first area and the second area may be formed in the first inclined direction in which the at least one second connection hole is disposed, and a boundary between the second area and the third area may be formed in the second inclined direction in which the at least one third connection hole is disposed.

According to one or more aspects of the present disclosure, a display apparatus may be provided that has a data link structure capable of reducing the bezel of a display panel.

According to one or more aspects of the present disclosure, a display apparatus may be provided that has a bezel reduction data link structure capable of improving image quality.

According to one or more aspects of the present disclosure, a display apparatus may be provided that has a bezel reduction data link structure capable of improving the performance of transmitting a common driving voltage.

According to one or more aspects of the present disclosure, a display apparatus may be provided that has a bezel reduction data link structure capable of correcting display artifacts such as some image display defects perceived as patterns.

According to one or more aspects of the present disclosure, a display apparatus and/or a display panel may be provided that has a reduced weight by reducing the bezel of the display panel based on an improved data link structure.

### BRIEF DESCRIPTION OF THE SEVERAL VIEWS OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates an example system configuration of a display apparatus according to aspects of the present disclosure;

FIG. 2 illustrates an example display panel according to aspects of the present disclosure;

FIG. 3 is an example cross-sectional view of the display panel according to aspects of the present disclosure;

FIG. 4 illustrates an example substrate of the display panel according to aspects of the present disclosure;

FIG. 5 is an example plan view of the display panel according to aspects of the present disclosure and illustrates a data link structure configured in the display panel;

FIG. 6 is another example plan view of the display panel according to aspects of the present disclosure and illustrates an example data link structure capable reducing the bezel of the display panel;

FIG. 7 illustrates example three areas defined in an active area by the bezel reduction data link structure of the display panel according to aspects of the present disclosure;

FIG. 8 illustrates an example area of the display panel with the bezel reduction data link structure according to aspects of the present disclosure; and

FIG. 9 is an example cross-sectional view taken along line A-A′ of FIG. 8 according to aspects of the present disclosure.

### DETAILED DESCRIPTION

Reference is now be made in detail to aspects of the present disclosure, examples of which may be illustrated in the accompanying drawings. In the following description, when a detailed description of well-known functions, structures or configurations may unnecessarily obscure aspects of the present disclosure, a detailed description of such known functions or configurations may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the aspects described with reference to the accompanying drawings. The present disclosure may, however, be embodied in different forms and should not be construed as limited to the example aspects set forth herein. Rather, these example aspects are examples and are provided so that this disclosure may be thorough and complete to assist those skilled in the art to understand the inventive concepts without limiting the protected scope of the present disclosure.

Shapes (e.g., sizes, lengths, widths, heights, thicknesses, locations, radii, diameters, and areas), dimensions, ratios, angles, numbers, and the like disclosed herein, including those illustrated in the drawings, are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

Where a term like “comprise,” “have,” “include,” “contain,” “constitute,” “make up of,” “formed of,” or the like is used with respect to one or more other elements, one or more other elements may be added unless a term, such as “only” or the like is used. The terms used in the present disclosure are merely used in order to describe example aspects, and are not intended to limit the scope of the present disclosure. The terms of a singular form may include plural forms unless the context clearly indicates otherwise.

The word “exemplary” is used to mean serving as an example or illustration, unless otherwise specified. Aspects are example aspects. Aspects are example aspects. “Aspects,” “examples,” “aspects,” and the like should not be construed as preferred or advantageous over other implementations. An aspect, an example, an example aspect, an aspect, or the like may refer to one or more aspects, one or more examples, one or more example aspects, one or more aspects, or the like, unless stated otherwise. Further, the term “may” encompasses all the meanings of the term “can.”

In one or more aspects, unless explicitly stated otherwise, element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

In describing a positional relationship when the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more other parts may be located between the two parts unless a more limiting term, such as “immediate(ly),” “direct(ly),” or “close(ly),” is used. For example, where a structure is described as being positioned “on,” “upon,” “on top of,” “over,” “under,” “above,” “below,” “beneath,” “near,” “close to,” “adjacent to,” “beside,” “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

It is understood that, although the terms “first,” “second,” or the like may be used herein to describe various elements (e.g., layers, films, regions, components, sections, or the like), these elements should not be limited by these terms, for example, to any particular order, precedence, or number of elements. These terms are used only to distinguish one element from another. For example, a first element could be termed a second element, and, similarly, a second element could be termed a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” or “(b),” or the like may be used. These terms are intended to identify the corresponding element(s) from the other element(s), and these are not used to define the essence, basis, order, or number of the elements.

It is understood that, although the terms “first,” “second,” or the like may be used herein to describe various elements (e.g., layers, films, regions, components, sections, or the like), these elements should not be limited by these terms, for example, to any particular order, precedence, or number of elements. These terms are used only to distinguish one element from another. For example, a first element could be termed a second element, and, similarly, a second element could be termed a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

For the expression that an element (e.g., layer, film, region, component, section, or the like) is described as “connected,” “coupled,” “attached,” “adhered,” or the like to another element, the element can not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, or the like) is “provided in,” “disposed in,” or the like in another element may be understood as that at least a portion of the element is provided in, disposed in, or the like in another element, or that the entirety of the element is provided in, disposed in, or the like in another element. The phase that an element (e.g., layer, film, region, component, section, or the like) “contacts,” “overlaps,” or the like with another element may be understood as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other. Such terms may mean a wider range of lines or directions within which the components of the present disclosure can operate functionally. For example, the terms “first direction,” “second direction,” and the like, such as a direction parallel or perpendicular to “X-axis,” “Y-axis,” or “Z-axis,” should not be interpreted only based on a geometrical relationship in which the respective directions are parallel or perpendicular to each other, and may be meant as directions having wider directivities within the range within which the components of the present disclosure can operate functionally.

The term “at least one” should be understood as including any and all combinations of one or more of the associated listed items. For example, each of the phrases of “at least one of a first item, a second item, or a third item” and “at least one of a first item, a second item, and a third item,” may represent (i) a combination of items provided by two or more of the first item, the second item, and the third item or (ii) only one of the first item, the second item, or the third item.

The expression of a first element, a second elements, “and/or” a third element should be understood to encompass one of the first, second, and third elements, as well as any and all combinations of the first, second and third elements. By way of example, A, B and/or C encompass only A; only B; only C; any of A, B, and C (e.g., A, B, or C); or some combinations of A, B, and C (e.g., A and B; A and C; or B and C); and all of A, B, and C. Furthermore, an expression “A/B” may be understood as A and/or B. For example, an expression “A/B” can refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as different from one another. In another example, an expression “different from one another” may be understood as different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various aspects of the present disclosure may be partially or entirely coupled to or combined with each other, may be technically associated with each other, and may be operated, linked, or driven together in various ways. Aspects of the present disclosure may be implemented or carried out independently from each other, or may be implemented or carried out together in a co-dependent or related relationship. In one or more aspects, the components of each apparatus according to various aspects of the present disclosure may be operatively coupled and configured.

Unless otherwise defined, the terms (including technical and scientific terms) used herein have the same meaning as commonly understood by one of ordinary skill in the art to which example aspects belong. It should be further understood that terms, such as those defined in commonly used dictionaries, should be interpreted as having a meaning that is, for example, consistent with their meaning in the context of the relevant art and should not be interpreted in an idealized or overly formal sense, unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example aspects.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

X-axis direction,” “Y-axis direction” and “Z-axis direction” should not be construed by a geometric relation only of a mutual vertical relation and may have broader directionality within the range that elements of the present disclosure may act functionally.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

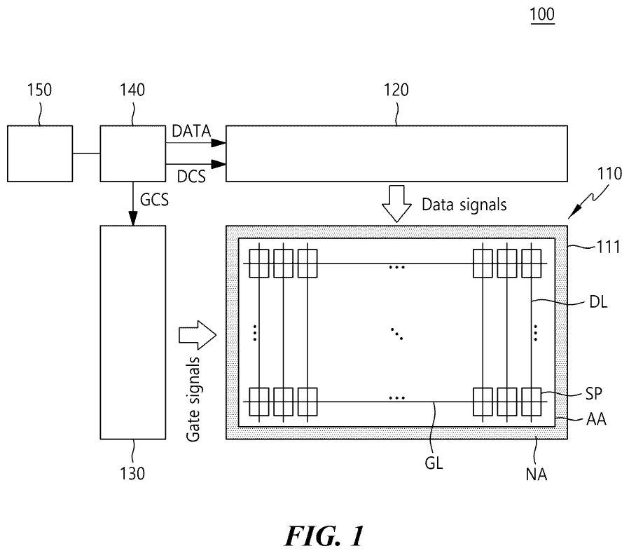

FIG. 1 illustrates an example system configuration of a display apparatus 100 according to aspects of the present disclosure. All components of each display apparatus according to all aspects of the present disclosure are operatively coupled and configured.

Referring to FIG. 1, in one or more aspects, the display apparatus 100 may include a display panel 110 and a display driving circuit, as elements configured to display images. The display driving circuit may be a circuit configured to drive the display panel 110, and include a data driving circuit 120, a gate driving circuit 130, a controller 140, and other circuit components.

The display panel 110 may include a substrate 111 and a plurality of subpixels SP disposed on the substrate 111.

The substrate 111 may include an active area AA allowing an image to be displayed and a non-active area NA disposed outside of the active area.

A plurality of subpixels SP for displaying images may be disposed in the active area AA. The non-active area NA may include a pad area PA, and the like. For example, the pad area PA may be a portion of the non-active area NA disposed in a first direction (e.g., a column direction or a row direction) from the active area AA.

According to aspects of the present disclosure, the display panel 110 may be configured to have a very small non-active area NA. Herein, the non-active area NA may also be referred to as “bezel.” For example, the non-active area NA may include a first non-active area disposed outside of the active area AA in the first direction, a second non-active area disposed outside of the active area AA in the second direction, a third non-active area disposed outside of the active area AA in a direction opposite to the first direction, and a fourth non-active area disposed outside of the active area AA in a direction opposite to the second direction. The first non-active area among the first to fourth non-active areas may include a pad area to which a driving circuit is connected or bonded (or attached). Among the first to fourth non-active areas, the second to fourth non-active areas that may not include a pad area may have a very small size compared to the first non-active area.

In another example, a boundary area may be between the active area AA and the non-active area NA. In this example, the non-active area NA may be bent at a certain angle to the active area AA, and thereby, may be located under the active area AA. In this implementation, when a user views the display apparatus 100 in front thereof, all or most of the non-active area NA may not be visible to the user. But aspects of the present disclosure are not limited thereto.

Various types of signal lines for driving a plurality of subpixels SP may be disposed on the substrate 111 of the display panel 110.

In some aspects, the display apparatus 100 herein may be a liquid crystal display apparatus, or the like, or a self-emission display apparatus in which light is emitted from the display panel 110 itself. In an example where the display apparatus 100 is the self-emission display apparatus, each of the plurality of subpixels SP may include a light emitting element. But aspects of the present disclosure are not limited thereto.

For example, the display apparatus 100 according to aspects of the present disclosure may be an organic light emitting display apparatus in which the light emitting element is implemented using an organic light emitting diode (OLED). In another example, the display apparatus 100 according to aspects of the present disclosure may be an inorganic light emitting display apparatus in which the light emitting element is implemented using an inorganic material-based light emitting diode. In another example, the display apparatus 100 according to aspects of the present disclosure may be a quantum dot display apparatus in which the light emitting element is implemented using quantum dots, which are self-emission semiconductor crystals. But aspects of the present disclosure are not limited thereto.

The structure of each of the plurality of subpixels SP may vary depend on types of display apparatus 100. For example, in an example where the display apparatus 100 is a self-emission display apparatus including self-emission subpixels SP, each subpixel SP may include a self-emission light emitting element, one or more transistors, and one or more capacitors.

The various types of signal lines may include, for example, a plurality of data lines DL for transmitting data signals (which may be referred to as data voltages or image signals), a plurality of gate lines GL for transmitting gate signals (which may be referred to as scan signals), and the like.

In one or more aspects, the plurality of data lines DL and the plurality of gate lines GL may intersect one another. Each of the plurality of data lines DL may be configured to extend in a first direction, and each of the plurality of gate lines GL may be configured to extend in a second direction. For example, the first direction may be the column or vertical direction, and the second direction may be the row or horizontal direction. In another example, the first direction may be the row or horizontal direction, and the second direction may be the column or vertical direction. Hereinafter, for convenience of explanation, discussions are provided based on examples where each of the plurality of data lines DL is disposed in the column direction and each of the plurality of gate lines GL is disposed in the row direction, but aspects of the present disclosure are not limited thereto.

The data driving circuit 120 may be a circuit for driving a plurality of data lines DL and can output data signals to the plurality of data lines DL.

The data driving circuit 120 can receive image data DATA in a digital form from the controller 140, and convert the received image data DATA into data signals in an analog form, and output converted data signals to the plurality of data lines DL.

In some aspects, the data driving circuit 120 may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, aspects of the present disclosure are not limited thereto.

The data driving circuit 120 may be disposed in, and/or electrically connected to, but not limited to, only one side or edge (e.g., an upper portion or a lower portion) of the display panel 110. In some aspects, the data driving circuit 120 may be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit 120 may be connected to outside, or a periphery, of the active area AA of the display panel 110, or be disposed in the active area AA of the display panel 110.

The gate driving circuit 130 may be a circuit configured to drive a plurality of gate lines GL and can output gate signals to the plurality of gate lines GL.

The gate driving circuit 130 can receive various types of gate driving control signals GCS, and further, receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In some aspects, the gate driving circuit 130 in the display apparatus 100 may be embedded into the display panel 110 by a gate-in-panel (GIP) technique. In an example where the gate driving circuit 130 is implemented by the gate-in-panel (GIP) technique, the gate driving circuit 130 may be disposed on the substrate 111 of the display panel 110 during the manufacturing process of the display panel 110 or display apparatus 100.

In one aspect, the gate driving circuit 130 may be disposed in the non-active area NA of the display panel 110.

In another aspect, the gate driving circuit 130 may be disposed in the active area AA of the display panel 110. In this implementation, for example, the gate driving circuit 130 may be disposed in, and/or electrically connected to, but not limited to, a portion of a first area (e.g., a left area or a right area) of the active area AA of the display panel 110. In another example, the gate driving circuit 130 may be disposed in, and/or electrically connected to, but not limited to, a portion of a first area (e.g., a left area or a right area) and a portion of a second area (e.g., the right area or the left area) of the active area AA of the display panel 110.

Herein, the gate driving circuit 130 embedded in the display panel 110 by the gate-in-panel (GIP) technique may also be referred to as a “gate-in-panel circuit.”

The controller 140 may be a device configured to control the data driving circuit 120 and the gate driving circuit 130, and can control driving timing for the plurality of data lines DL and driving timing for the plurality of gate lines GL.

The controller 140 can supply a data control signal DCS to the data driving circuit 120 to control the data driving circuit 120, and supply a gate control signal GCS to the gate driving circuit 130 to control the gate driving circuit 130.

The controller 140 can receive image data input from a host system 150 and supply image data DATA readable by the data driving circuit 120 based on the input image data to the data driving circuit 120.

The controller 140 may be implemented in a separate component from the data driving circuit 120, or integrated with the data driving circuit 120, so that the controller 140 and the data driving circuit 120 can be implemented in a single integrated circuit.

The controller 140 may be a timing controller used in the typical display technology or a control apparatus/device capable of additionally performing other control functionalities in addition to the typical function of the timing controller. In one or more embodiments, the controller 140 may be one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like.

The controller 140 may be mounted on a printed circuit board, a flexible printed circuit, or the like, and may be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces may include a low voltage differential signaling (LVDS) interface, an embedded clock point-point interface (EPI), a serial peripheral interface (SPI), and the like. However, aspects of the present disclosure are not limited thereto.

In one or more aspects, to provide a touch sensing function, as well as an image display function, the display apparatus 100 may include a touch sensor, and a touch sensing circuit configured to sense the touch sensor and detect whether a touch is applied by an object such as a finger, a pen, or the like, or a location of the touch (or touch coordinates).

The touch sensing circuit may include a touch driving circuit configured to drive and sense the touch sensor and generate and output touch sensing data, and a touch controller configured to detect whether a touch is applied or a location of the touch (or touch coordinates) based on the touch sensing data.

The touch sensor may include a plurality of touch electrodes. The touch sensor may further include a plurality of touch lines for electrically connecting the plurality of touch electrodes to the touch driving circuit.

The touch sensor may be disposed outside of the display panel 110 in the form of a touch panel or may be disposed inside of the display panel 110. The touch sensor disposed outside of the display panel 110 may be referred to as an add-on type touch sensor. In the example where the add-on type of touch sensor is disposed in the display apparatus 100, the touch panel and the display panel 110 may be separately manufactured and combined in an assembly process. The add-on type of touch panel may include a touch panel substrate and a plurality of touch electrodes disposed on the touch panel substrate.

In the example where the touch sensor is disposed inside of the display panel 110, the touch sensor may be formed on the substrate along with signal lines and electrodes related to display driving during the manufacturing process of the display panel 110.

The touch driving circuit can supply a touch driving signal to at least one of a plurality of touch electrodes and generate touch sensing data by sensing at least one of the plurality of touch electrodes.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on a capacitance between one or more touch electrode and an object such as a finger, a pen, and/or the like. According to the self-capacitance sensing technique, each of a plurality of touch electrodes can serve as both a driving touch electrode and a sensing touch electrode. The touch driving circuit may drive all, or one or more, of a plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes. According to the mutual-capacitance sensing technique, a plurality of touch electrodes may be divided into driving touch electrodes and sensing touch electrodes. The touch driving circuit can drive the driving touch electrodes and sense the sensing touch electrodes.

In one or more aspects, the touch driving circuit and touch controller included in the touch sensing circuit may be implemented in separate devices or in a single device. In one or more aspects, the touch driving circuit and the data driving circuit may be implemented in separate devices or in a single device.

The display apparatus 100 may further include a power supply circuit configured to supply various types of power to the display driving circuit and/or the touch sensing circuit.

In some aspects, the display apparatus 100 may be a mobile terminal such as a smart phone, a tablet, or the like, or a monitor, a television (TV), or the like. Such apparatuses may be configured in various types, sizes, and shapes. The display apparatus 100 according to aspects of the present disclosure are not limited thereto, and may include various types, sizes, and shapes configured to display information or images, a display apparatus according to the aspects of the present disclosure may be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

In one or more aspects, the display apparatus 100 may further include an electronic apparatus such as a camera (e.g., an image sensor), a sensor capable of detecting an object, and the like. For example, the sensor may be a sensor capable of detecting an object or a human body by receiving light such as infrared light, ultrasonic light, ultraviolet light or the like.

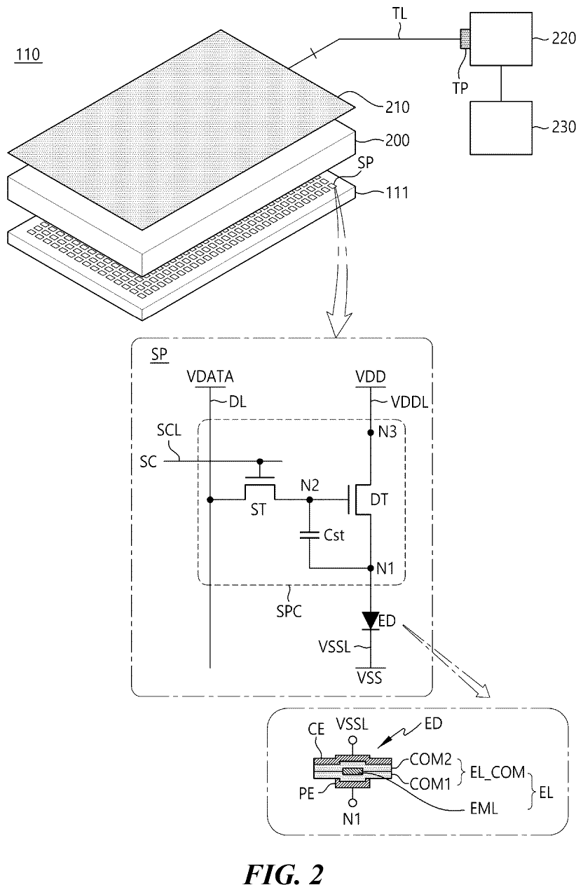

FIG. 2 illustrates an example configuration of the display panel 110 according to aspects of the present disclosure.

Referring to FIG. 2, the display panel 110 may include a substrate 111 on which a plurality of subpixels SP are disposed, and an encapsulation layer 200 over the substrate 111. The encapsulation layer 200 may also be referred to as an encapsulation substrate, an encapsulation stack, or the like.

Referring to FIG. 2, in an example where the display apparatus 100 is a self-emission display apparatus, each of the plurality of subpixels SP disposed on the substrate 111 may include a light emitting element ED and a subpixel circuit SPC for driving the light emitting element ED.

Referring to FIG. 2, the subpixel circuit SPC may include a plurality of transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of transistors may include a driving transistor DT for driving the light emitting element ED and a scan transistor ST configured to be turned on or off according to a scan signal SC.

The driving transistor DT can supply a driving current to the light emitting element ED.

The scan transistor ST may be configured to control an electrical state of a corresponding node in the subpixel circuit SPC or to control the state or operation of the driving transistor DT.

The at least one capacitor may include a storage capacitor Cst configured to maintain a constant voltage during a display frame or a certain period of the display frame.

Referring to FIG. 2, to drive a subpixel SP, a data signal VDATA, which is an image signal, and a scan signal SC, which is a gate signal, may be applied to the subpixel SP. Further, a common pixel driving voltage including a first common driving voltage VDD and a second common driving voltage VSS may be applied to the subpixel SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode commonly disposed in all or some of a plurality of subpixels SP. For example, the pixel electrode PE may be an anode, and the common electrode CE may be a cathode. In another example, the pixel electrode PE may be a cathode, and the common electrode CE may be an anode. Hereinafter, for convenience of explanation, discussions are provided based on examples where the pixel electrode PE is an anode, and the common electrode CE is a cathode.

In an example where the light emitting element ED is an organic light emitting diode, the intermediate layer EL may include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 may be referred to as a common intermediate layer EL_COM.

The emission layer EML may be disposed in each subpixel SP, and the common intermediate layer EL_COM may be commonly disposed across all or some of a plurality of subpixels SP.

The emission layer EML may be disposed in each light emitting area, and the common intermediate layer EL_COM may be commonly disposed across all or some of a plurality of light emitting areas and all or some of a plurality of non-light emitting areas.

For example, the first common intermediate layer COM1 may include a hole injection layer (HIL), a hole transfer layer (HTL), and the like. The second common intermediate layer COM2 may include an electron transport layer (ETL), an electron injection layer (EIL), and the like. But aspects of the present disclosure are not limited thereto.

The hole injection layer can inject holes from the pixel electrode PE to the hole transport layer, the hole transport layer can transport holes to the emission layer EML, the electron injection layer can inject electrons from the common electrode CE to the electron transport layer, and the electron transport layer can transport electrons to the emission layer EML.

For example, the common electrode CE may be electrically connected to a second common driving voltage line VSSL. A second common driving voltage VSS, which is a type of common pixel driving voltage, may be applied to the common electrode CE through the second common driving voltage line VSSL. The pixel electrode PE may be electrically connected directly or indirectly (via another transistor) to a first node N1 of a corresponding driving transistor DT of each subpixel SP. Herein, the second common driving voltage VSS may also be referred to as a “base voltage,” and the second common driving voltage line VSSL may also be referred to as a “low power supply voltage line,” a “low voltage line,” or a “base voltage line.

Each light emitting element ED may be configured by overlapping of the pixel electrode PE, the emission layer in the intermediate layer EL, and the common electrode CE. Each light emitting element ED may form a corresponding light emitting area. For example, a corresponding light emitting area of each light emitting element ED may include an overlapping area of the pixel electrode PE, the emission layer in the intermediate layer EL, and the common electrode CE.

In some aspects, the light emitting element ED may be an organic light emitting diode (OLED), an inorganic light emitting diode (LED), or a quantum dot light emitting element. For example, in an example where the light emitting element ED is an organic light emitting diode OLED, the intermediate layer EL of the light emitting element ED may be a layer including an organic material. But aspects of the present disclosure are not limited thereto.

The driving transistor DT may be a transistor configured to supply a driving current to the light emitting element ED. The driving transistor DT may be connected between a first common driving voltage line VDDL and the light emitting element ED.

The driving transistor DT may include a first node N1, a second node N2, and a third node N3. The first node N1 may be electrically connected to the light emitting element ED. A data signal VDATA may be applied to the second node N2. The first common driving voltage VDD through the first common driving voltage line VDDL may be applied to the third node N3.

In the driving transistor DT, the second node N2 may be a gate node, the first node N1 may be a source node or a drain node, and the third node N3 may be the drain node or the source node. Hereinafter, for merely convenience of explanation, discussions are provided based on examples where the first, second, and third nodes (N1, N2, and N3) of the driving transistor DT are source, gate, and drain nodes, respectively. However, aspects of the present disclosure are not limited thereto.

The scan transistor ST included in the subpixel circuit SPC illustrated in FIG. 2 may be a switching transistor for allowing a data signal VDATA, which is an image signal, to be supplied to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST may be electrically connected to the data line DL. The source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed to be located or disposed outside of the driving transistor DT, and therefore, be different from an internal capacitor such as a parasitic capacitor (e.g., a Cgs, a Cgd) that may be formed between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

In an example where the display panel 110 has the top emission structure, at least a portion of the subpixel circuit SPC may overlap with at least a portion of the light emitting element ED in the vertical direction. In this configuration, the area or size of a corresponding light emitting area can be increased, and a corresponding aperture ratio can be increased.

In an example where the display panel 110 has the bottom emission structure, the subpixel circuit SPC may not overlap with the light emitting element ED in the vertical direction.

As shown in FIG. 2, the subpixel circuit SPC may include two transistors (2T: DT and ST) and one capacitor (1C: Cst) (which may be referred to as a “2T1C structure”), and in some implementations, may further include one or more transistors, and/or further include one or more capacitors.

For example, the subpixel circuit SPC may have an 8T1C structure including 8 transistors and 1 capacitor. In another example, the subpixel circuit SPC may have an 6T2C structure including 6 transistors and 2 capacitor. In further another example, the subpixel circuit SPC may have an 7T1C structure including 7 transistors and 1 capacitor.

The types and number of gate signals supplied to a subpixel SP, and/or the types and number of gate lines connected to the subpixel SP may vary depending on a structure of a corresponding subpixel circuit SPC. Further, the types and number of common pixel driving voltages supplied to a subpixel SP may vary depending on a structure of a corresponding subpixel circuit SPC.

Since circuit elements (e.g., a light emitting element ED such as an organic light emitting diode (OLED) including an organic material) in each subpixel SP are vulnerable to external moisture or oxygen, an encapsulation layer 200 may be disposed in the display panel 110 to prevent the external moisture or oxygen from penetrating into the circuit elements (e.g., the light emitting element ED). The encapsulation layer 200 may be disposed in various shapes or configurations to prevent light emitting elements ED from contacting moisture or oxygen. For example, the encapsulation layer 200 may include two or more layers of organic and inorganic layers alternately stacked, but aspects of the present disclosure are not limited thereto.

Referring to FIG. 2, in one or more aspects, to sense a touch of a user, the display apparatus 100 may include a touch sensor stack 210 including a plurality of sensor electrodes, a touch driving circuit 220 configured to sense the plurality of sensor electrodes, and a touch controller 230 configured to determine whether a touch is applied or a location of the touch (e.g., touch coordinates) based on the sensing result (e.g., touch sensing data) of the touch driving circuit 220.

The touch sensor stack 210 may be embedded in the display panel 110. For example, the touch sensor stack 210 may be disposed on the encapsulation layer 200 of the display panel 110.

The display panel 110 may include a plurality of touch pads TP to which the touch driving circuit 220 is electrically connected, and a plurality of touch routing lines for electrically connecting the plurality of sensor electrodes included in the touch sensor stack 210 to the plurality of touch pads TP to which the touch driving circuit 220 is connected.

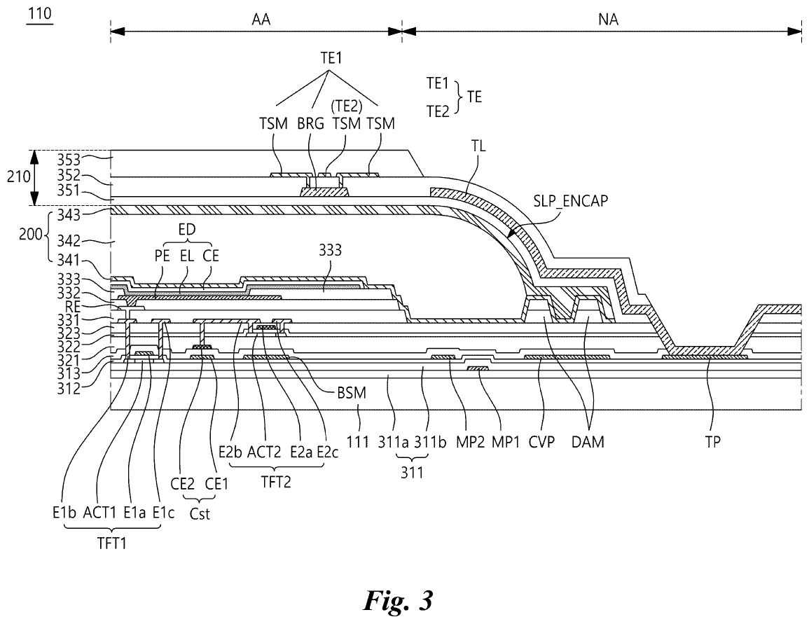

FIG. 3 is an example cross-sectional view of the display panel 110 according to aspects of the present disclosure.

Referring to FIG. 3, in some aspects, in terms of stack-up configuration, the display panel 110 may include a subpixel circuit stack, a light emitting element stack, and an encapsulation stack.

The subpixel circuit stack may include a substrate 111, various types of insulating layers (311, 312, 313, 321, 322, and 323) on the substrate 111, various types of transistors (TFT1 and TFT2), a storage capacitor Cst, and various electrodes or signal lines.

Transistors (TFT1 and TFT2) included in the subpixel circuit stack may include a first transistor TFT1, a second transistor TFT2, and the like.

The first transistor TFT1 may include a first active layer ACT1, a first electrode E1a, a second electrode E1b, and a third electrode E1c. The first active layer ACT1 may be a first semiconductor layer, but aspects of the present disclosure are not limited thereto. For example, the first active layer ACT1 may be configured with an oxide semiconductor, amorphous silicon, polysilicon, low-temperature polysilicon (LTPS), or the like, but aspects of the present disclosure are not limited thereto. The first transistor TFT1 may be a p-channel transistor or an n-channel transistor, but aspects of the present disclosure are not limited thereto.

The first electrode E1a may be a gate electrode, the second electrode E1b may be a source electrode or a drain electrode, and the third electrode E1c may be the drain electrode or the source electrode. Hereinafter, for convenience of explanation, discussions are provided based on examples where the first, second, and third electrodes (E1a, E1b, and E1c) are a first gate electrode E1a, a first source electrode E1b, and a first drain electrode E1c, respectively.

The second transistor TFT2 may include a second active layer ACT2, a fourth electrode E2a, a fifth electrode E2b, and a sixth electrode E2c. The second active layer ACT2 may be a second semiconductor layer, but aspects of the present disclosure are not limited thereto. For example, the second active layer ACT2 may be configured with an oxide semiconductor, amorphous silicon, polysilicon, low-temperature polysilicon (LTPS), or the like, but aspects of the present disclosure are not limited thereto. The second transistor TFT2 may be a p-channel transistor or an n-channel transistor, but aspects of the present disclosure are not limited thereto. For example, one of the first transistor TFT1 and the second transistor TFT2 may include an active layer having an oxide semiconductor. In another example, one of the first transistor TFT1 and the second transistor TFT2 may include an active layer having low-temperature polysilicon. In further another example, the first transistor TFT1 and the second transistor TFT2 may include an active layer having an oxide semiconductor. In another example, one or more transistors in a gate driver configured in the gate-in-panel (GIP) type may include active layers having an oxide semiconductor or low temperature polysilicon. In another example, all transistors configured on the substrate and transistors included in a gate driver configured in the gate-in-panel (GIP) type may include active layers having an oxide semiconductor.

The fourth electrode E2a may be a gate electrode, the fifth electrode E2b may be a source electrode or a drain electrode, and the sixth electrode E2c may be the drain electrode or the source electrode. Hereinafter, for convenience of explanation, discussions are provided based on examples where the fourth, fifth, and sixth electrodes (E2a, E2b, and E2c) are a second gate electrode E2a, a second source electrode E2b, and a second drain electrode E2c, respectively.

The second active layer ACT2 of the second transistor TFT2 may be disposed higher from the substrate 111 than the first active layer ACT1 of the first transistor TFT1.

A first buffer layer 311 may be disposed under the first active layer ACT1 of the first transistor TFT1, and a second buffer layer 321 may be disposed under the second active layer ACT2 of the second transistor TFT2. For example, the first active layer ACT1 of the first transistor TFT1 may be disposed on the first buffer layer 311, and the second active layer ACT2 of the second transistor TFT2 may be disposed on the second buffer layer 321. The second buffer layer 321 may be disposed higher than the first buffer layer 311.

The storage capacitor Cst may be disposed in various metal layers in the display panel 110. For example, the storage capacitor Cst may include a first capacitor electrode CE1 and a second capacitor electrode CE2.

The light emitting element stack may include a plurality of light emitting elements ED disposed on at least one planarization layer (331, and/or 332). Each of the light emitting elements ED may include a pixel electrode PE, an intermediate layer EL, and a common electrode CE.

The encapsulation stack may include an encapsulation layer 200 on the plurality of light emitting elements ED. The encapsulation layer 200 may include a single layer or multiple layers. The encapsulation stack may further include at least one dam DAM in addition to the encapsulation layer 200.

Hereinafter, the stack-up configuration of the display panel 110 according to aspects of the present disclosure will be described in more detail with reference to FIG. 3.

Referring to FIG. 3, the first buffer layer 311 may be disposed on the substrate 111. The first buffer layer 311 may include a single layer or multiple layers. In an example where the first buffer layer 311 has a stack of multiple layers, the first buffer layer 311 may include a multi-buffer layer 311a and an active buffer layer 311b.

The first active layer ACT1 of the first transistor TFT1 may be disposed on the first buffer layer 311. The first active layer ACT1 may include a channel region where a channel is formed, a source connection region on one side of the channel region, and a drain connection region on another side of the channel region.

Referring to FIG. 3, a first gate insulating layer 312 may be disposed on the first active layer ACT1 of the first transistor TFT1. The first gate electrode E1a of the first transistor TFT1 may be disposed on the first gate insulating layer 312. A first interlayer insulating layer 313 may be disposed on the first gate electrode E1a of the first transistor TFT1.

Referring to FIG. 3, the second buffer layer 321 may be disposed on the first interlayer insulating layer 313.

Referring to FIG. 3, the second active layer ACT2 of the second transistor TFT2 may be disposed on the second buffer layer 321. The first active layer ACT2 may include a channel region where a channel is formed, a source connection region on one side of the channel region, and a drain connection region on another side of the channel region.

Referring to FIG. 3, a second gate insulating layer 322 may be disposed on the second active layer ACT2 of the second transistor TFT2. The second gate electrode E2a of the second transistor TFT2 may be disposed on the second gate insulating layer 322. A second interlayer insulating layer 323 may be disposed on the second gate electrode E2a of the second transistor TFT2.

Referring to FIG. 3, the first source electrode E1b and the first drain electrode E1c of the first transistor TFT1 and the second source electrode E2b and the second drain electrode E2c of the second transistor TFT2 may be disposed on the second interlayer insulating layer 323.

The first source electrode E1b and the first drain electrode E1c of the first transistor TFT1 may be connected to the source connection region and the drain connection region of the first active layer ACT1 respectively through respective holes in each of the second interlayer insulating layer 323, the second gate insulating layer 322, the second buffer layer 321, the first interlayer insulating layer 313, and the first gate insulating layer 312.

The second source electrode E2b and the second drain electrode E2c of the second transistor TFT2 may be connected to the source connection region and drain connection region of the second active layer ACT2 respectively through respective holes in each of the second interlayer insulating layer 323 and the second gate insulating layer 322.

Referring to FIG. 3, the first source electrode E1b and the first drain electrode E1c of the first transistor TFT1 and the second source electrode E2b and the second drain electrode E2c of the second transistor TFT2 may include a first metal and may be disposed in a first metal layer. The first metal and the first metal layer may be referred to as a first source-drain metal and a first source-drain metal layer, respectively.

Referring to FIG. 3, in one or more aspects, the storage capacitor Cst may be configured with the first capacitor electrode CE1 and the second capacitor electrode CE2. In one or more aspects, the storage capacitor Cst may include three or more capacitor electrodes, or may include two or more capacitors connected in parallel.

Referring to FIG. 3, each of the first capacitor electrode CE1 and the second capacitor electrode CE2 may be disposed in various metal layers in the display panel 110.

In one or more aspects, the first capacitor electrode CE1 may include the same first gate metal as the first gate electrode E1a of the first transistor TFT1 on the first gate insulating layer 312, and be disposed in a first gate metal layer.

In one or more aspects, the second capacitor electrode CE2 may be disposed on the first interlayer insulating layer 313.

Referring to FIG. 3, the second source electrode E2b of the second transistor TFT2 may be electrically connected to the second capacitor electrode CE2 through respective holes of the second interlayer insulating layer 323, the second gate insulating layer 322, and the second buffer layer 321.

In one or more aspects, the first transistor TFT1 may be the driving transistor DT of FIG. 2, and the second transistor TFT2 may be the scan transistor ST of FIG. 2.

Referring to FIG. 3, the subpixel circuit stack may further include various metal patterns (e.g., a first metal pattern MP1, a second metal pattern MP2, and the like). For example, the first metal pattern MP1 may be disposed between the multi-buffer layer 311a and the active buffer layer 311b included in the first buffer layer 311. The second metal pattern MP2 may include the same first gate metal as the first gate electrode E1a of the first transistor TFT1 and may be disposed in the first gate metal layer. In one or more aspects, the first metal pattern MP1 may be a first metal layer, and the second metal pattern MP2 may be a second metal layer. However, aspects of the present disclosure are not limited thereto.

The first metal pattern MP1, the second metal pattern MP2, and a common driving voltage pattern CVP may be disposed in the active area AA or the non-active area NA.

Referring to FIG. 3, the subpixel circuit stack may further include a shielding layer BSM disposed on the substrate 111, overlapping with the second active layer ACT2 of the second transistor TFT2, and disposed under the second active layer ACT2 of the second transistor TFT2.

For example, the shielding layer BSM may be disposed in the same first gate metal layer as the first gate electrode E1a of the first transistor TFT1. In another example, the shielding layer BSM may be disposed in the same metal layer as the first metal pattern MP1 on the first buffer layer 311.

An additional shielding layer BSM may be disposed under the first active layer ACT1 of the first transistor TFT1 and overlap with the first active layer ACT1 of the first transistor TFT1. In this implementation, the shielding layer BSM may be disposed in the same metal layer as the first metal layer MP1.

Referring to FIG. 3, the subpixel circuit stack may further include the common driving voltage pattern CVP to which a common driving voltage is applied. The common driving voltage applied to the common driving voltage pattern CVP may be a power signal, and for example, be the first common driving voltage VDD or the second common driving voltage VSS in FIG. 2. The first common driving voltage VDD may be referred to as a high power supply voltage (or a high power signal), and the second common driving voltage VSS may be referred to as a low power supply voltage (or a low power signal) or a base voltage.

The common driving voltage pattern CVP may be disposed in the active area AA or the non-active area NA.

At least one planarization layer may be disposed on the first transistor TFT1 and the second transistor TFT2. FIG. 3 illustrates, for example, two planarization layers (first and second planarization layers 331 and 332) disposed on the first transistor TFT1 and the second transistor TFT2. In one or more aspects, three or more planarization layers may be disposed on the first transistor TFT1 and the second transistor TFT2 according to design requirements. However, aspects of the present disclosure are not limited thereto.

Referring to FIG. 3, the first planarization layer 331 may be disposed on the first source electrode E1b and the first drain electrode E1c of the first transistor TFT1 and the second source electrode E2b and the second drain electrode E2c of the second transistor TFT2. In one or more aspects, the first planarization layer 331 may be configured to cover both the first transistor TFT1 and the second transistor TFT2.

Referring to FIG. 3, a relay electrode RE may be disposed on the first planarization layer 331. The relay electrode RE may be electrically connected to the first source electrode E1b of the first transistor TFT1 through a hole of the first planarization layer 331.

The relay electrode RE may be disposed in a second metal layer on the first planarization layer 331, and include a second metal. The second metal and the second metal layer may be referred to as a second source-drain metal and a second source-drain metal layer, respectively.

Referring to FIG. 3, the second planarization layer 332 may be disposed on the relay electrode RE.

Referring to FIG. 3, the light emitting element stack may be disposed on the second planarization layer 332. A light emitting element ED may be formed on the second planarization layer 332. The light emitting element ED may include a pixel electrode PE, an intermediate layer EL, and a common electrode CE. The light emitting area of the light emitting element ED may be formed in an area where the pixel electrode PE, the intermediate layer EL, and the common electrode CE overlap and contact each other.

The pixel electrode PE may be disposed on the second planarization layer 332, and a bank 333 may be disposed on the pixel electrode PE. An opening of the bank 333 may expose a portion of the pixel electrode PE to form the light emitting area. For example, the opening of the bank 333 may overlap with a portion of the pixel electrode PE.

The intermediate layer EL of the light emitting element ED may be disposed on a portion of the pixel electrode PE and the bank 333. The common electrode CE may be disposed on the intermediate layer EL.

Referring to FIG. 3, the encapsulation stack may be disposed on the light emitting element stack, and be disposed on the common electrode CE. The encapsulation stack may include an encapsulation layer 200 disposed on the common electrode CE.

The encapsulation layer 200 can prevent moisture or oxygen from penetrating into the light emitting element ED. For example, the encapsulation layer 200 can prevent moisture or oxygen from penetrating into an organic material contained in the intermediate layer EL of the light emitting element ED. In one or more aspects, the encapsulation layer 200 may include a single layer or multiple layers, but aspects of the present disclosure are not limited thereto.

Referring to FIG. 3, for example, the encapsulation layer 200 may include a first encapsulation layer 341, a second encapsulation layer 342, and a third encapsulation layer 343. The first encapsulation layer 341 and the third encapsulation layer 343 may include, for example, an inorganic layer, and the second encapsulation layer 342 may include, for example, an organic layer.

In one or more aspects, as described above, a touch sensor may be embedded in the display panel 110. In these aspects, the display panel 110 may include a touch sensor stack 210 disposed on the encapsulation layer 200.

Referring to FIG. 3, the touch sensor stack 210 may include a plurality of touch electrodes TE, and include touch sensor metals TSM and bridge metals BRG to form the plurality of touch electrodes TE. For example, a touch sensor metal TSM may be formed from a mesh having a conductive grid structure with one or more openings (hereinafter, which may be referred to as a mesh-type touch electrode).

Referring to FIG. 3, the touch sensor stack 210 may further include one or more insulating layers such as a sensor buffer layer 351 on the encapsulation layer 200, a sensor interlayer insulating layer 352 on the sensor buffer layer 351, and/or a sensor protective layer 353 on the sensor interlayer insulating layer 352.

Each of the plurality of touch electrodes TE may be configured with one or more touch sensor metals TSM. In this implementation, each of the plurality of touch electrodes TE may be a mesh-type touch electrode with a plurality of openings.

The plurality of touch electrodes TE may include one or more first touch electrodes TE1 and one or more second touch electrodes TE2. Two or more touch sensor metals TSM, or two or more parts of one touch sensor metal TSM, included in each first touch electrode TE1 or each second touch electrode TE2 may be electrically connected through one or more bridge metals BRG.

The sensor buffer layer 351 may be disposed on the encapsulation layer 200, the bridge metals BRG may be disposed on the sensor buffer layer 351, and the sensor interlayer insulating layer 352 may be disposed on the bridge metals BRG.

The touch sensor metals TSM may be disposed on the sensor interlayer insulating layer 352. in one or more aspects, the touch sensor metals TSM may include one or more first touch sensor metals and one or more second touch sensor metals, and the bridge metals BRG may include one or more first bridge metals BRG and one or more second bridge metals BRG. In this implementation, respective portions of first touch sensor metals TSM may be connected to corresponding one or more first bridge metals BRG through holes in the sensor interlayer insulating layer 352.

Referring to FIG. 3, one or more first touch sensor metals TSM and one or more second bridge metals BRG may be configured not to overlap with each other. The touch sensor metals TSM and the bridge metals BRG may overlap with the bank 333.

In one or more aspects, a plurality of touch sensor metals TSM may be included in one touch electrode TE, be mesh-type touch electrodes, and be electrically connected to each other. In one or more aspects, among the plurality of touch sensor metals TSM, one or more touch sensor metals TSM and one or more other touch sensor metals TSM may be electrically connected to each other through one or more bridge metals BRG to form one touch electrode TE.

The sensor protective layer 353 may be configured to cover the touch sensor metals TSM and the bridge metals BRG.

Referring to FIG. 3, a touch line TL may electrically connect a touch electrode TE to a touch pad TP. The touch line TL may be formed with at least one of a touch sensor metal TSM and a bridge metal BRG. For example, the touch line TL may be a portion of the touch sensor metal TSM or the bridge metal BRG.

In an example where the display panel 110 is a display panel in which a touch sensor is embedded, the touch line TL may extend along an outer slope SLP_ENCAP of the encapsulation layer 200 and an upper portion of at least one dam DAM and extend to the touch pad TP disposed in the non-active area NA.

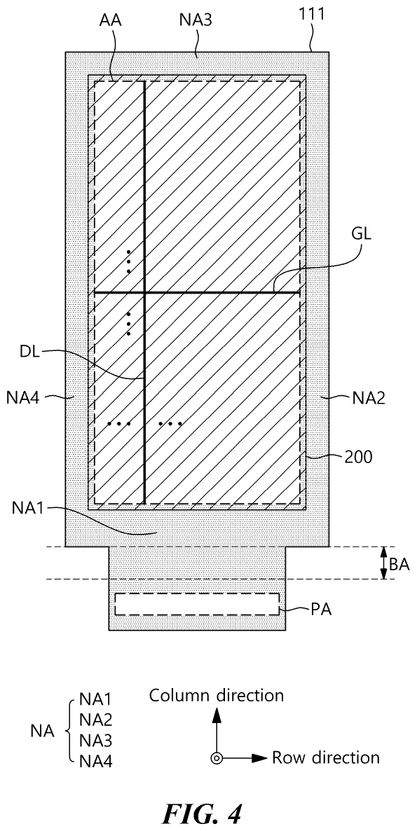

FIG. 4 illustrates an example structure of a substrate (e.g., the substrate 111 of FIG. 3) included in the display panel 110 according to aspects of the present disclosure.

Referring to FIG. 4, in one or more aspects, the substrate 111 of the display panel 110 may include an active area AA allowing an image to be displayed and a non-active area NA in which an image is not displayed.

Referring to FIG. 4, the non-active area NA may include, for example, a first non-active area, a second non-active area NA2, a third non-active area NA3, and a fourth non-active area NA4. But aspects of the present disclosure are not limited thereto.

The first non-active area NA1 may be located at a first side of the active area AA. The second non-active area NA2 may be located at a second side of the active area AA. The third non-active area NA3 may be located at a third side of the active area AA. The fourth non-active area NA4 may be located at a fourth side of the active area AA.

For example, the first and third sides may be opposite sides in the column direction. The second and fourth sides may be opposite sides in the row direction. In another example, the first and third sides may be opposite sides in the row direction. The second and fourth sides may be opposite sides in the column direction. Hereinafter, for convenience of explanation, discussions are provided based on examples where the first and third sides are opposite sides in the column direction, and the second and fourth sides are opposite sides in the row direction.

For example, the column direction may be a direction in which data lines DL extend, and the row direction may be a direction in which gate lines GL extend. In another example, the column direction may be a direction in which gate lines GL extend, and the row direction may be a direction in which data line DL extend. Hereinafter, for convenience of explanation, discussions are provided based on examples where the column direction is the direction in which data lines DL extend, and the row direction is the direction in which gate lines GL extend.

Referring to FIG. 4, the first non-active area NA1 may include a pad area PA. A plurality of pads to which at least one driving circuit or a printed circuit board is electrically connected may be disposed at the pad area PA. In one or more aspects, a plurality of data lines DL, a first common driving voltage line VDDL, and a second common driving voltage line VSSL may be electrically connected to the plurality of pads.

Referring to FIG. 4, the first non-active area NA1 may further include a bending area BA. In this implementation, the substrate 111 may be a flexible substrate. In one or more aspects, the first non-active area NA1 may be not including a bending area BA.

Referring to FIG. 4, the display panel 110 may further include a ground line disposed in the non-active area NA of the substrate 111. The ground line may be disposed such that it runs from one point of the pad area PA to another point of the pad area PA via the second non-active area NA2, the third non-active area NA3, and the fourth non-active area NA4.

Referring to FIG. 4, in one or more aspects, the encapsulation layer 200 disposed in the display panel 110 may have a structure in which at least one inorganic layer and at least one organic layer are stacked. In these aspects, an edge of the encapsulation layer 200 may be an edge of an organic layer. The encapsulation layer 200 may extend from the active area AA to a portion of the non-active area NA.

Referring to FIG. 4, in one or more aspects, to prevent the overflow of an organic layer included in the encapsulation layer 200, the display panel 110 may further include at least one dam or at least one stopper disposed outwards more than the organic layer included in the encapsulation layer 200. The at least one dam or the at least one stopper may include an organic layer, but aspects of the present disclosure are not limited thereto.

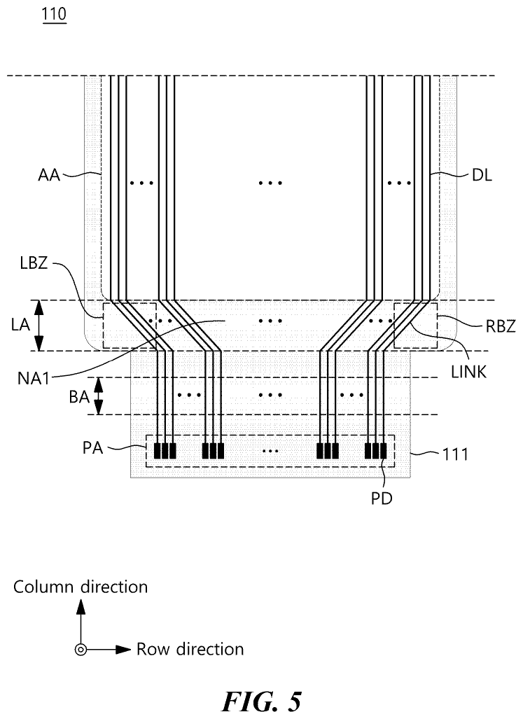

FIG. 5 is an example plan view of the display panel 110 according to aspects of the present disclosure, and illustrates a data link structure configured in the display panel 110.

Referring to FIG. 5, in one or more aspects, the display panel 110 may include a plurality of data lines DL configured to deliver data voltages VDATA, and a plurality of pads PD disposed at the pad area PA and configured to allow the data driving circuit 120 to be electrically connected.

Referring to FIG. 5, in one or more aspects, the display panel 110 may include a data link structure configured to electrically connect the plurality of data lines DL to the plurality of pads PD. In one or more aspects, the data link structure may include a plurality of data link lines LINK.

Referring to FIG. 5, the plurality of data link lines LINK may be disposed in the non-active area NA For example, the plurality of data link lines LINK may be disposed in the first non-active area NA1 including a pad area PA.

Referring to FIG. 5, the first non-active area NA1 may further include a link area LA in addition to the pad area PA and a bending area BA.

For example, each of the plurality of data link lines LINK may be disposed across the pad area PA, the bending area BA, and the link area LA. Each of the plurality of data link lines LINK may include a first end (or a first edge) electrically connected to a pad PD disposed in the pad area PA, and a second end (or a second edge) electrically connected to a data line DL disposed in the active area AA. A portion between both ends (i.e., the first and second ends, or the first and second edges) of each of the plurality of data link lines LINK may be disposed across the bending area BA and the link area LA.

For example, each of the plurality of data link lines LINK may be formed from one line or two or more lines. Each of the plurality of data link lines LINK may be disposed in one metal layer or in two or more metal layers.

Referring to FIG. 5, the bending area BA may be bent during the manufacturing process of the display panel 110. Accordingly, when a user views the display apparatus 100 in front thereof, the bending area BA and the pad area PA may not be visible to the user.

However, when a user views the display apparatus 100 in front thereof, the link area LA may be recognized as a bezel even when it is covered by a case or cover member. Therefore, to implement a narrow bezel, it may be desirable to reduce the area or size of the link area LA.

Referring to FIG. 5, the area or size of the link area LA becomes great because all of a plurality of data link lines LINK in the link area LA of the first non-active area NA1 are needed to be electrically connected to a plurality of data lines DL.

For example, when a length of the pad area PA in the second direction (row direction) is less than a length of the active area AA in the second direction (row direction), each of a plurality of data link lines LINK in left and right areas (LBZ and RBZ) of the link area LA is needed to extend at a certain angle to the row direction or the column direction and thereafter be electrically connected to a corresponding one of the plurality of data lines DL. This configuration causes the link area LA in the first direction (column direction) to have an increased length and the link area LA to have an increased area.

Accordingly, as shown in FIG. 5, in the example where the display panel 110 has a data link structure in which a plurality of data link lines LINK are disposed in the first non-active area NA1, the area or size of the link area LA of the first non-active area NA1 may become great. In this implementation, when a user views the display apparatus 100 in front thereof, the link area LA may be recognized as a wide bezel.

Therefore, in implement a narrow bezel, it is desirable to provide a data link structure capable of reducing the area of the link area LA. To meet such a requirement, a data link structure capable of implementing a narrow bezel is provided as discussed below.

Hereinafter, a data link structure capable of implementing a narrow bezel according to aspects of the present disclosure is described.

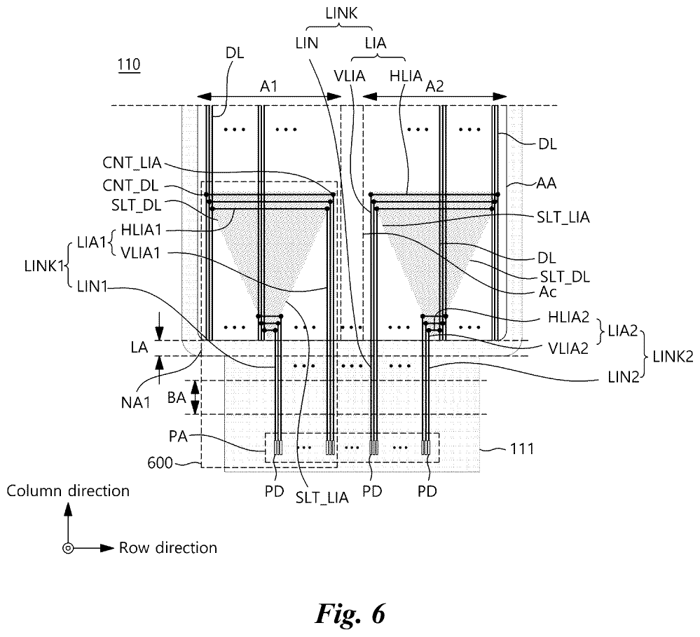

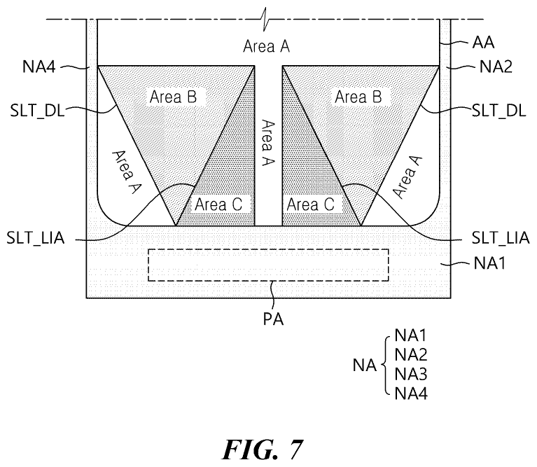

FIG. 6 is another example plan view of the display panel 110 according to aspects of the present disclosure, and illustrates an example data link structure capable reducing the bezel of the display panel 110 (“bezel reduction data link structure”). FIG. 7 illustrates an example of three areas (A, B, and C areas) defined in the active area AA by the bezel reduction data link structure of the display panel 110 according to aspects of the present disclosure.

Referring to FIG. 6, the non-active area NA may include a first non-active area NA1 disposed in the column direction from the active area AA. The first non-active area NA1 may include a pad area PA and a link area LA disposed in the column direction from the active area AA.

In one or more aspects, the display panel 110 may include a data link structure configured to supply data voltages VDATA to a plurality of subpixels SP disposed in the active area AA and reduce the bezel of the display panel 110.

Referring to FIG. 6, in one or more aspects, this bezel reduction data link structure may include a plurality of data link lines LINK for electrically connecting a plurality of data lines DL to a plurality of pads PD.

The plurality of data lines DL may be disposed in the active area AA, extend in the column direction, and be connected to a plurality of subpixels SP disposed in the active area AA.

The plurality of pads PD may be disposed in the pad area PA included in the first non-active area NA1.

The plurality of data link lines LINK may electrically connect the plurality of pads PD disposed in the pad area PA in the first non-active area NA1 to the plurality of data lines DL disposed in the active area AA.

Referring to FIG. 6, in the data link structure for implementing the narrow bezel according to aspects of the present disclosure, a portion LIA of each of the plurality of data link lines LINK may be disposed in the active area AA.

In the bezel reduction data link structure according to aspects of the present disclosure, the plurality of data link lines LINK and the plurality of data lines DL may be electrically connected to each other in the active area AA. For example, in the bezel reduction data link structure according to aspects of the present disclosure, connection points CNT_DL in which the plurality of data link lines LINK and the plurality of data lines DL are connected to each other may be disposed in the active area AA.

According to these configurations, each of the plurality of data link lines LINK may be not needing to extend at a certain angle to the row direction or the column direction in left and right areas of the link area LA, and each of the plurality of data link lines LINK may pass through the link area LA with a short length in the column direction, enter the active area AA, and be connected to a corresponding data line DL in the active area AA.

As shown in FIG. 6, in the example where the display panel 110 has the bezel reduction data link structure, the length of the link area LA in the column direction may be very short or be zero. Accordingly, the first non-active area NA1 viewed by a user in front of the display panel 110 may become very small.

Referring to FIG. 6, in the bezel reduction data link structure according to aspects of the present disclosure, each of the plurality of data link lines LINK may include a link line LIA of the active area AA (which may be referred to as an active area link line LIA), which may be disposed in the active area AA.

Each active area link line LIA may include a horizontal link line HLIA disposed in the active area AA and extending in the row direction (i.e., the horizontal direction), and a vertical link line VLIA disposed at least partially in the active area AA and extending in the column direction (i.e., the vertical direction).

Referring to FIG. 6, each vertical link line VLIA may electrically connect a corresponding pad PD to a corresponding horizontal link line HLIA, and each horizontal link line HLIA may electrically connect a corresponding vertical link line VLIA to a corresponding data line DL.

Referring to FIG. 6, each horizontal link line HLIA and each vertical link line VLIA may be electrically connected to each other through a corresponding link line connection hole CNT_LIA. Each horizontal link line HLIA and each data line DL may be electrically connected to each other through a corresponding data line connection hole CNT_DL.

In one or more aspects, since one or more data line connection holes CNT_DL or one or more link line connection holes CNT_LIA may be not evenly distributing across the entire area of the display panel 110. Therefore, there may occur differences in the density of distributed connection holes. Due to these differences in density of distributed connection holes, the display apparatus may suffer from display artifacts such as some image display defects perceived as patterns.

Referring to FIG. 6, each of a plurality of data link lines LINK may further include a link line LIN of the non-active area NA (which may be referred to as a non-active area link line LIN), which may be disposed in the first non-active area NA1 of the non-active area NA.

For example, each non-active area link line LIN and a corresponding vertical link line VLIA may be formed in a single line. In another example, each non-active area link line LIN may be electrically connected to a corresponding vertical link line VLIA, and be disposed in a metal layer different from a metal layer in which the vertical link line VLIA is disposed. In further another example, each non-active area link line LIN may include a line electrically connected to a corresponding vertical link line VLIA and disposed in a metal layer different from a metal layer in which the vertical link line VLIA is disposed.

In the example where the display panel 110 has the bezel reduction data link structure as shown in FIG. 6, a horizontal link line HLIA included in each of a plurality of data link lines LINK may extend parallel to a plurality of gate lines GL disposed in the active area AA and extending in the row direction (the horizontal direction).

Further, in the example where the display panel 110 has the bezel reduction data link structure as shown in FIG. 6, the horizontal link line HLIA included in each of the plurality of data link lines LINK may overlap with at least one gate line GL in the vertical direction.

Referring to FIG. 6, among a plurality of vertical link lines VLIA, a vertical link line VLIA electrically connected to a data line DL disposed closer to the center of the active area AA may have a relatively short length. Among the plurality of vertical link lines VLIA, a vertical link line VLIA electrically connected to a data line DL further away from the center of the active area AA may have a length greater than a vertical link line VLIA electrically connected to a data line DL disposed close to the center of the active area AA. Among the plurality of vertical link lines VLIA, a vertical link line VLIA electrically connected to a data line DL disposed closer to the center of the active area AA may have a length shorter than a vertical link line VLIA electrically connected to a data line DL away from the center of the active area AA. But aspects of the present disclosure are not limited thereto.

Among a plurality of horizontal link lines HLIA, a horizontal link line HLIA electrically connected to a data line DL disposed closer to the center of the active area AA may have a relatively short length. Among the plurality of horizontal link lines HLIA, a horizontal link line HLIA electrically connected to a data line DL further away from the center of the active area AA may have a length greater than a horizontal link line HLIA electrically connected to a data line DL disposed close to the center of the active area AA. Among the plurality of horizontal link lines HLIA, a horizontal link line HLIA electrically connected to a data line DL disposed closer to the center of the active area AA may have a length shorter than a horizontal link line HLIA electrically connected to a data line DL away from the center of the active area AA. But aspects of the present disclosure are not limited thereto.

Referring to FIG. 6, among a plurality of horizontal link lines HLIA, a horizontal link line HLIA closer to the pad area PA may have a relatively short length. Among the plurality of horizontal link lines HLIA, a horizontal link line HLIA further away from the pad area PA may have a relatively great length. Among the plurality of horizontal link lines HLIA, a horizontal link line HLIA closer to the pad area PA may have a length shorter than a horizontal link line HLIA away from the pad area PA. But aspects of the present disclosure are not limited thereto.

Referring to FIG. 6, a first link line LINK1 may include a first active area link line LIA1 and a first non-active area link line LIN1. The first active area link line LIA1 may include a first horizontal link line HLIA1 and a first vertical link line VLIA1.

Referring to FIG. 6, a second link line LINK2 may include a second active area link line LIA2 and a second non-active area link line LIN2. The second active area link line LIA2 may include a second horizontal link line HLIA2 and a second vertical link line VLIA2.

Referring to FIG. 6, among the first vertical link line VLIA1 and the second vertical link line VLIA2, the first vertical link line VLIA1 electrically connected to a first data line DL1 disposed more outwards among the first data line DL1 and a second data line DL2 may have a length greater than the second vertical link line VLIA2.

Referring to FIG. 6, among the first horizontal link line HLIA1 and the second horizontal link line HLIA2, the first horizontal link line HLIA1 electrically connected to the first data line DL1 disposed more outwards among the first data line DL1 and the second data line DL2 may have a length greater than the second horizontal link line HLIA2.

Referring to FIG. 6, since the first horizontal link line HLIA1 has a length greater than the second horizontal link line HLIA2, a first area where the first horizontal link line HLIA1 overlaps with at least one gate line GL may be greater than a second area where the second horizontal link line HLIA2 overlaps with at least one gate line GL.

As discussed above, as shown in FIG. 6, points CNT_DL where data lines DL and horizontal link lines HLIA are connected may be disposed in two first virtual slant lines SLT_DL. Further, points CNT_LIA where vertical link lines VLIA and horizontal link lines HLIA are connected may be disposed in two second virtual slant lines SLT_LIA.

As shown in FIG. 6, two triangles may be formed by the two first virtual slant lines SLT_DL and the two second virtual slant lines SLT_LIA. In each of the two triangles, one of three sides may be a horizontal side parallel to the horizontal link lines HLIA, and a vertex facing this horizontal side may be located in a boundary between the active area AA and the first non-active area NA1 or be located at a place near the boundary.

Referring to FIG. 6, the active area AA may include a central area Ac, a first area A1 on a first side of the central area Ac, and a second area A2 on a second opposing side of the central area Ac.

Referring to FIG. 6, data lines DL disposed in the first area A1 and the second area A2 may be connected to non-active area link lines LIN through active area link lines LIA.

Referring to FIG. 6, in one or more aspects, at least one data line DL disposed in the central area Ac may be directly connected to a corresponding non-active area link line LIN without an active area link line LIA.

As discussed above, in the example where the display panel 110 has the bezel reduction data link structure as shown in FIG. 6, respective horizontal link lines HLIA of a plurality of link lines LINK may be parallel to a plurality of gate lines GL disposed in the active area AA and extending in the row direction (the horizontal direction), and respective horizontal link lines HLIA of the plurality of link lines LINK may overlap with at least one gate line GL in the vertical direction.

Referring to FIG. 7, according to the bezel reduction data link structure described above, the active area AA may include three areas (A, B, and C), which are distinctly defined.

Referring to FIG. 7, a first area (Area A) may be an area in which the bezel reduction data link structure is not configured. A second area (Area B) and a third area (Area C) may be areas where the bezel reduction data link structure is configured. The second area (Area B) may be an area where horizontal link lines HLIA are disposed, and the third area (Area C) may be an area where vertical link lines VLIA are disposed.

Referring to FIG. 7, among the first to fourth non-active areas (NA1 to NA4) included in the non-active area NA, the first non-active area NA1 including the pad area PA may contact one side of each third area (Area C).

Referring to FIG. 7, the second area (Area B) may have an inverted triangle shape or an isosceles triangle shape, but aspects of the present disclosure are not limited thereto. The active area AA may include two second areas (Area B). The two second areas (Area B) may be respectively disposed on both sides of the first area (Area A) disposed in the central area of the active area AA.

Referring to FIG. 7, the third area (Area C) may have a right triangle shape, but aspects of the present disclosure are not limited thereto. The active area AA may include two third areas (Area C). The two third areas (Area C) may be respectively disposed on both sides of the first area (Area A) located in the central area of the active area AA.

Referring to FIG. 7, the first area (Area A) may be disposed on (or the top of) the two second areas (Area B), also be disposed between the two third areas (Area C), and also be disposed outside of the two second areas (Area B). The first area (Area A) disposed between the two third areas (Area C) may correspond to the central area Ac of FIG. 6. Referring to FIGS. 6 and 7, the first area (Area A), the second area (Area B), and the third area (Area C) may be differently arranged and/or may each have a different shape from those shown in FIGS. 6 and 7 in other aspects of the present disclosure. For example, FIG. 7 shows adjacent third areas (Area C) having a portion of the first area (Area A) that is interposed therebetween so as to overlap with a central area of the display panel 110. However, the active area AA need not have the portion of the first area (Area A) be overlapped or coinciding with the central area of the display panel 110. Rather, adjacent third areas (area C) may be combined to form a single third area (Area C) in a form of an isosceles triangle. Also, referring to FIGS. 6 and 7, a shape of the second area (Area B) may need not be an isosceles triangle as shown, but may be a polygon, such as a trapezoid, a parallelogram or others. When the second area (Area B) is a parallelogram, the length of the first link lines HLIA1 or the second link lines HLIA2 may be the same.

Referring to FIGS. 6 and 7, a boundary between the first area (Area A) and each of the two second areas (Area B) may correspond to points CNT_DL where horizontal link lines HLIA and data lines DL are connected, and form the first virtual slant line SLT_DL.

Referring to FIGS. 6 and 7, a boundary between each second area (Area B) and each third area (Area C) may correspond to points CNT_LIA where vertical link lines VLIA and horizontal link lines HLIA are connected, and form the second virtual slant line SLT_LIA. As shown in FIG. 7, the first virtual slant line SLT_DL and the second virtual slant line SLT_LIA are slanted in different directions relative to the horizontal or vertical direction. But aspects of the present disclosure are not limited thereto. For example, the first virtual slant line SLT_DL and the second virtual slant line SLT_LIA may be parallel, or be slanted in the same direction.

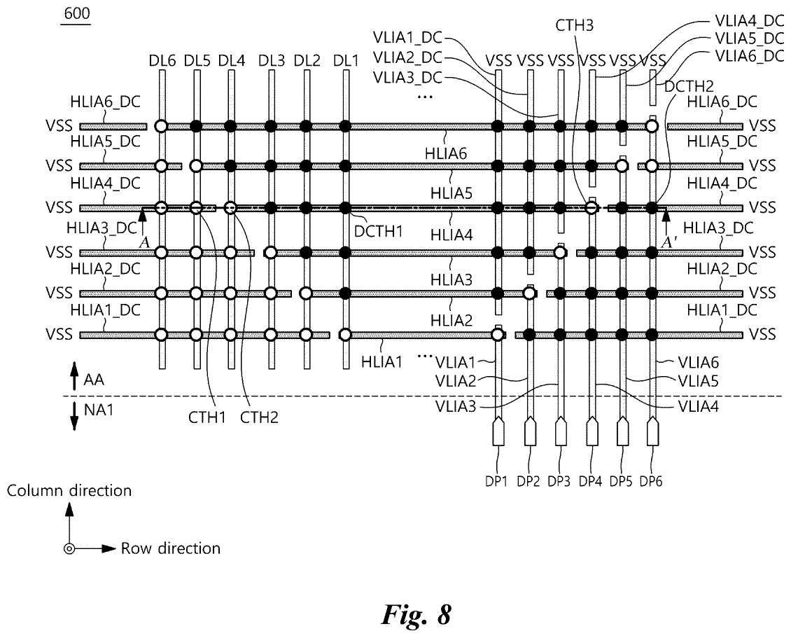

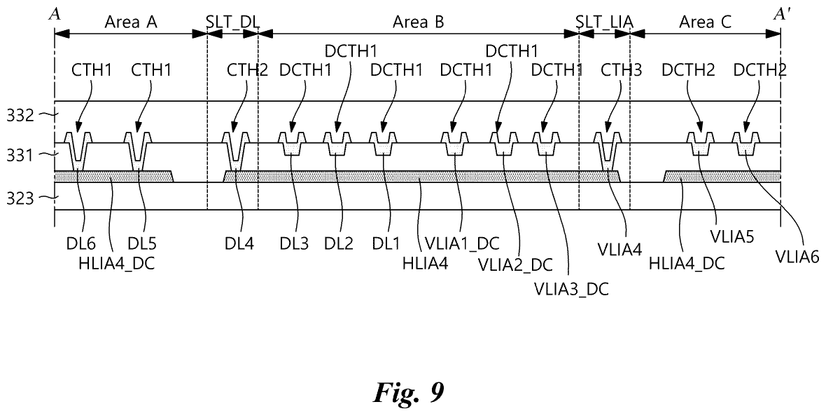

FIG. 8 is an example area of the display panel 110 with a data link structure (e.g., the bezel reduction data link structure discussed above) according to aspects of the present disclosure. FIG. 9 is a cross-sectional view taken along line A-A′ of FIG. 8.

Referring to FIG. 8, the first non-active area NA1 may include a pad area PA where a plurality of data pads (DP1 to DP6) are disposed. The plurality of data pads (DP1 to DP6) may include a first data pad DP1, a second data pad DP2, a third data pad DP3, a fourth data pad DP4, a fifth data pad DP5, and a sixth data pad DP6. But aspects of the present disclosure are not limited thereto, and additional data pads may be disposed.

Referring to FIG. 8, a plurality of data lines DL may be disposed in the active area AA, and include a first data line DL1, a second data line DL2, a third data line DL3, a fourth data line DL4, a fifth data line DL5, and a sixth data line DL6. But aspects of the present disclosure are not limited thereto, and additional data lines may be disposed. Each of the first data line DL1, the second data line DL2, the third data line DL3, the fourth data line DL4, the fifth data line DL5, and the sixth data line DL6 may be disposed in the active area AA, and extend in the column direction. A corresponding data voltage may be applied to each of the first data line DL1, the second data line DL2, the third data line DL3, the fourth data line DL4, the fifth data line DL5, and the sixth data line DL6.

Referring to FIGS. 8 and 6, a data link structure (e.g., the bezel reduction data link structure discussed above) may be configured in a portion of the active area AA adjacent to the first non-active area NA1.

Referring to FIGS. 8 and 6, the bezel reduction data link structure may include active area link lines LIA, and the active area link lines LIA may include horizontal link lines HLIA and vertical link lines VLIA.

Each of the horizontal link lines HLIA may be disposed in the active area AA. All or at least part of each of the vertical link lines VLIA may be disposed in the active area AA.

In one or more aspects, in the display panel 110, data line connection holes CNT_DL through which horizontal link lines HLIA and data lines DL are electrically connected may be referred to as second connection holes CTH2, and link line connection holes CNT_LIA through which horizontal link lines HLIA and vertical link lines VLIA are electrically connected may be referred to as third connection holes CTH3.

Referring to FIG. 8, the horizontal link lines HLIA may include a first horizontal link line HLIA1 electrically connected to the first data line DL1, disposed in the active area AA, extending in the row direction, and disposed in a first metal layer ML1. The first horizontal link line HLIA1 may be electrically connected to the first data line DL1 through a second connection hole CTH2.

Further, the vertical link lines VLIA may include a first vertical link line VLIA1 electrically interconnecting the first horizontal link line HLIA1 and the first data pad DP1, extending in the column direction, and disposed in a second metal layer ML2 different from the first metal layer ML1. The first vertical link line VLIA1 may be electrically connected to the first horizontal link line HLIA1 through a third connection hole CTH3. All or at least part of the first vertical link line VLIA1 may be disposed in the active area AA.

Referring to FIG. 8, the horizontal link lines HLIA may include a second horizontal link line HLIA2 electrically connected to the second data line DL2, disposed in the active area AA, extending in the row direction, and disposed in the first metal layer ML1. The second horizontal link line HLIA2 may be electrically connected to the second data line DL2 through a second connection hole CTH2.

Further, the vertical link lines VLIA may include a second vertical link line VLIA2 electrically inter connecting the second horizontal link line HLIA2 and the second data pad DP2, extending in the column direction, and disposed in the second metal layer ML2 different from the first metal layer ML1. The second vertical link line VLIA2 may be electrically connected to the second horizontal link line HLIA2 through a third connection hole CTH3. All or at least part of the second vertical link line VLIA2 may be disposed in the active area AA.

Referring to FIG. 8, the horizontal link lines HLIA may include a third horizontal link line HLIA3 electrically connected to the third data line DL3, disposed in the active area AA, extending in the row direction, and disposed in the first metal layer ML1. The third horizontal link line HLIA3 may be electrically connected to the third data line DL3 through a second connection hole CTH2.

Further, the vertical link lines VLIA may include a third vertical link line VLIA3 electrically interconnecting the third horizontal link line HLIA3 and the third data pad DP3, extending in the column direction, and disposed in the second metal layer ML2 different from the first metal layer ML1. The third vertical link line VLIA3 may be electrically connected to the third horizontal link line HLIA3 through a third connection hole CTH3. All or at least part of the third vertical link line VLIA3 may be disposed in the active area AA.

Referring to FIG. 8, the horizontal link lines HLIA may include a fourth horizontal link line HLIA4 electrically connected to the fourth data line DL4, disposed in the active area AA, extending in the row direction, and disposed in the first metal layer ML1. The fourth horizontal link line HLIA4 may be electrically connected to the fourth data line DL4 through a second connection hole CTH2.

Further, the vertical link lines VLIA may include a fourth vertical link line VLIA4 electrically interconnecting the fourth horizontal link line HLIA4 and the fourth data pad DP4, extending in the column direction, and disposed in the second metal layer ML2 different from the first metal layer ML1. The fourth vertical link line VLIA4 may be electrically connected to the fourth horizontal link line HLIA4 through a third connection hole CTH3. All or at least part of the fourth vertical link line VLIA4 may be disposed in the active area AA.

Referring to FIG. 8, the horizontal link lines HLIA may include a fifth horizontal link line HLIA5 electrically connected to the fifth data line DL5, disposed in the active area AA, extending in the row direction, and disposed in the first metal layer ML1. The fifth horizontal link line HLIA5 may be electrically connected to the fifth data line DL5 through a second connection hole CTH2.

Further, the vertical link lines VLIA may include a fifth vertical link line VLIA5 electrically interconnecting the fifth horizontal link line HLIA5 and the fifth data pad DP5, extending in the column direction, and disposed in the second metal layer ML2 different from the first metal layer ML1. The fifth vertical link line VLIA5 may be electrically connected to the fifth horizontal link line HLIA5 through a third connection hole CTH3. All or at least part of the fifth vertical link line VLIA5 may be disposed in the active area AA.

Referring to FIG. 8, the horizontal link lines HLIA may include a sixth horizontal link line HLIA6 electrically connected to the sixth data line DL6, disposed in the active area AA, extending in the row direction, and disposed in the first metal layer ML1. The sixth horizontal link line HLIA6 may be electrically connected to the sixth data line DL6 through a second connection hole CTH2.

Further, the vertical link lines VLIA may include a sixth vertical link line VLIA6 electrically interconnecting the sixth horizontal link line HLIA6 and the sixth data pad DP6, extending in the column direction, and disposed in the second metal layer ML2 different from the first metal layer ML1. The sixth vertical link line VLIA6 may be electrically connected to the sixth horizontal link line HLIA6 through a third connection hole CTH3. All or at least part of the sixth vertical link line VLIA6 may be disposed in the active area AA.

Referring to FIGS. 8 and 7, in one or more aspects, in the display panel 110, the second connection holes CTH2 through which the data lines DL and the horizontal link lines HLIA are electrically connected may be disposed in a first slant direction SLT_DL relative to the horizontal or vertical direction. A boundary between the first area (Area A) and the second area (Area B) may be formed in the first slant direction STL_DL in which the second connection holes CTH2 are disposed.

In one or more aspects, in the display panel 110, the third connection holes CTH3 through which the horizontal link lines HLIA and the vertical link lines VLIA are electrically connected may be arranged in a second slant direction relative to the horizontal or vertical direction. A boundary between the second area (Area B) and the third area (Area C) may be formed in the second slant direction STL_LIA in which the third connection holes CTH3 are disposed.

Referring to FIGS. 8 and 7, in one or more aspects, the display panel 110 may further include a first horizontal metal pattern HLIA1_DC spaced apart from the first horizontal link line HLIA1, extending in the row direction, and disposed in the first metal layer ML1. The first horizontal metal pattern HLIA1_DC may include one first horizontal metal pattern HLIA1_DC disposed in the first area (Area A) and another first horizontal metal pattern HLIA1_DC disposed in the third area (Area C). The first horizontal metal pattern HLIA1_DC disposed in the first area (Area A) may be electrically connected to the second to sixth data lines (DL2 to DL6) through first connection holes CTH1.

Further, the display panel 110 may further include a first vertical metal pattern VLIA1_DC spaced apart from the first vertical link line VLIA1, extending in the column direction, and disposed in the second metal layer ML2.

Referring to FIGS. 8 and 7, in one or more aspects, the display panel 110 may further include a second horizontal metal pattern HLIA2_DC spaced apart from the second horizontal link line HLIA2, extending in the row direction, and disposed in the first metal layer ML1. The second horizontal metal pattern HLIA2_DC may include one second horizontal metal pattern HLIA2_DC disposed in the first area (Area A) and another second horizontal metal pattern HLIA2_DC disposed in the third area (Area C). The second horizontal metal pattern HLIA2_DC disposed in the first area (Area A) may be electrically connected to the third to sixth data lines (DL3 to DL6) through first connection holes CTH1.

Further, the display panel 110 may further include a second vertical metal pattern VLIA2_DC spaced apart from the second vertical link line VLIA2, extending in the column direction, and disposed in the second metal layer ML2.

Referring to FIGS. 8 and 7, in one or more aspects, the display panel 110 may further include a third horizontal metal pattern HLIA3_DC spaced apart from the third horizontal link line HLIA3, extending in the row direction, and disposed in the first metal layer ML1. The third horizontal metal pattern HLIA3_DC may include one third horizontal metal pattern HLIA3_DC disposed in the first area (Area A) and another third horizontal metal pattern HLIA3_DC disposed in the third area (Area C). The third horizontal metal pattern HLIA3_DC disposed in the first area (Area A) may be electrically connected to the fourth to sixth data lines (DL4 to DL6) through first connection holes CTH1.

Further, the display panel 110 may further include a third vertical metal pattern VLIA3_DC spaced apart from the third vertical link line VLIA3, extending in the column direction, and disposed in the second metal layer ML2.

Referring to FIGS. 8 and 7, in one or more aspects, the display panel 110 may further include a fourth horizontal metal pattern HLIA4_DC spaced apart from the fourth horizontal link line HLIA4, extending in the row direction, and disposed in the first metal layer ML1. The fourth horizontal metal pattern HLIA4_DC may include one fourth horizontal metal pattern HLIA4_DC disposed in the first area (Area A) and another fourth horizontal metal pattern HLIA4_DC disposed in the third area (Area C). The fourth horizontal metal pattern HLIA4_DC disposed in the first area (Area A) may be electrically connected to the fifth to sixth data lines (DL5 to DL6) through first connection holes CTH1.

Further, the display panel 110 may further include a fourth vertical metal pattern VLIA4_DC spaced apart from the fourth vertical link line VLIA4, extending in the column direction, and disposed in the second metal layer ML2.

Referring to FIGS. 8 and 7, in one or more aspects, the display panel 110 may further include a fifth horizontal metal pattern HLIA5_DC spaced apart from the fifth horizontal link line HLIA5, extending in the row direction, and disposed in the first metal layer ML1. The fifth horizontal metal pattern HLIA5_DC may include one fifth horizontal metal pattern HLIA5_DC disposed in the first area (Area A) and another fifth horizontal metal pattern HLIA5_DC disposed in the third area (Area C). The fifth horizontal metal pattern HLIA5_DC disposed in the first area (Area A) may be electrically connected to the sixth data line DL6 through a first connection hole CTH1.

Further, the display panel 110 may further include a fifth vertical metal pattern VLIA5_DC spaced apart from the fifth vertical link line VLIA5, extending in the column direction, and disposed in the second metal layer ML2.

Referring to FIGS. 8 and 7, in one or more aspects, the display panel 110 may further include a sixth horizontal metal pattern HLIA6_DC spaced apart from the sixth horizontal link line HLIA6, extending in the row direction, and disposed in the first metal layer ML1.

Further, the display panel 110 may further include a sixth vertical metal pattern VLIA6_DC spaced apart from the sixth vertical link line VLIA6, extending in the column direction, and disposed in the second metal layer ML2.

The first to sixth horizontal metal patterns (HLIA1_DC to HLIA6_DC) and the first to sixth vertical metal patterns (VLIA1_DC to VLIA6_DC) may serve as lines for delivering a low power supply voltage VSS, which is a second common driving voltage.

The first to sixth horizontal metal patterns (HLIA1_DC to HLIA6_DC) and the first to sixth vertical metal patterns (VLIA1_DC to VLIA6_DC) may be formed from a mesh having a conductive grid structure with one or more openings. As a result, since the low power supply voltage VSS, which is the second common driving voltage, is delivered through the first to sixth horizontal metal patterns (HLIA1_DC to HLIA6_DC) and the first to sixth vertical metal patterns (VLIA1_DC to VLIA6_DC), an area for delivering the low power supply voltage VSS can be increased, and the transfer characteristics of low power supply voltage VSS can also be greatly improved.

Further, as a first horizontal link line is segmented into the first horizontal link line HLIA1 and the first horizontal metal pattern HLIA1_DC, and a first vertical link line is segmented into the first vertical link line VLIA1 and the first vertical metal pattern VLIA1_DC, the length and area of a path through which a data voltage is transmitted can be reduced. As a result, parasitic capacitance related to the first data line DL1 can be reduced.

Likewise, as second to sixth horizontal link lines are segmented into the second to sixth horizontal link lines (HLIA2 to HLIA6) and the second to sixth horizontal metal patterns (HLIA2_DC to HLIA6_DC), respectively, and second to sixth vertical link lines are segmented into the second to sixth vertical link lines (VLIA2 to VLIA6) and the second to sixth vertical metal patterns (VLIA2_DC to VLIA6_DC), respectively, the lengths and areas of paths through which data voltages are transmitted can be reduced. As a result, parasitic capacitance related to the second to sixth data lines DL2 to DL6 can be reduced.

Reduction in parasitic capacitance related to the first to sixth data lines (DL1 to DL6) can help improve image quality.

Referring to FIGS. 8 and 7, in one or more aspects, in the first area (Area A) of the display panel 110, horizontal metal patterns HLIA_DC and data lines DL may be electrically connected to each other through first connection holes CTH1 at points where the horizontal metal patterns HLIA_DC and the data lines DL overlap with each other.

In one or more aspects, in a boundary between the first area (Area A) and the second area (Area B), data lines DL and horizontal link lines HLIA may be electrically connected to each other through second connection holes CTH2.

In one or more aspects, in a boundary between the second area (Area B) and the third area (Area C), horizontal link lines HLIA and vertical link lines VLIA may be electrically connected to each other through third connection holes CTH3.

In one or more aspects, in the second area (Area B), first dummy connection holes DCTH1 may be disposed in areas where each of data lines DL of the vertical metal patterns VLIA_DC overlaps with horizontal link lines HLIA.

In one or more aspects, in the third area C, second dummy connection holes DCTH2 may be disposed in areas where vertical link lines VLIA and horizontal metal patterns HLIA_DC overlap with each other.

In one or more aspects, in the display panel 110, first to third connection holes (CTH1 to CTH3) may be disposed in the first area (Area A), a boundary between the first area (Area A) and the second area (Area B), and a boundary between the second area (Area B) and the third area (Area C), respectively, and first dummy connection holes DCTH1 and second dummy connection holes DCTH2 may be disposed in the second area (Area B) and the third area (Area C), respectively. According to these configurations, display artifacts such as some image display defects perceived as patterns can be corrected by evenly distributing the connection holes and dummy connection holes across the entire area of the display panel 110.

Referring to FIGS. 8 and 9, the first horizontal link line HLIA1 and the first horizontal metal patterns HLIA1_DC may be disposed in the first metal layer ML1. Accordingly, first open areas where the first horizontal link line HLIA1 and the first horizontal metal patterns HLIA1_DC are separated into each other may also be referred to as first open areas of the first metal layer ML1.

Referring to FIGS. 8 and 9, the first vertical link line VLIA1 and the first vertical metal pattern VLIA1_DC may be disposed in the second metal layer ML2. Accordingly, a second open area where the first vertical link line VLIA1 and the first vertical metal pattern VLIA1_DC are separated into each other may also be referred to as a second open area of the second metal layer ML2.

In one or more aspects, referring to FIG. 7, one of the first open areas in the first metal layer ML1, in which the first horizontal link line HLIA1 and one of the first horizontal metal patterns HLIA1_DC are separated into each other, may be disposed at a boundary of the first area (Area A) and the second area (Area B) among the three areas (Area A, Area B, and Area C), which are distinct areas in the active area AA by the bezel reduction data link structure.

In one or more aspects, the other one of the first open areas in the first metal layer ML1, in which the first horizontal link line HLIA1 and the other one of the first horizontal metal patterns HLIA1_DC are separated into each other, and the second open area of the second metal layer ML2 may be disposed at a boundary between the second area (Area B) and the third area (Area C) among the three areas (Area A, Area B, and Area C), which are distinct areas in the active area AA by the bezel reduction data link structure.

Referring to FIGS. 8 and 9, the fourth horizontal link line HLIA4 and the fourth horizontal metal patterns HLIA4_DC may be disposed on a second interlayer insulating layer 323 (e.g., the second interlayer insulating layer 323 of FIG. 3) and spaced apart from each other.

Referring to FIGS. 8 and 9, a first planarization layer 331 (e.g., the first planarization layer 331 of FIG. 3) may be disposed on the fourth horizontal link line HLIA4 and the fourth horizontal metal patterns HLIA4_DC.

Referring to FIGS. 8 and 9, the data lines (DL1 to DL6), the first to third vertical metal patterns (VLIA1_DC to VLIA3_DC), and the fourth to sixth vertical link lines (VLIA4 to VLIA6) may be disposed on the first planarization layer 331.

Referring to FIG. 9, the fifth and sixth data lines (DL5 and DL6) may be connected to one of the fourth horizontal metal patterns HLIA4_DC through first connection holes CTH1 in the first planarization layer 331.

Referring to FIG. 9, the fourth data line DL4 may be connected to the fourth horizontal link line HLIA4 through a second connection hole CTH2 in the first planarization layer 331.

Referring to FIG. 9, the first to third data lines (DL1 to DL3) may be configured to overlap with the fourth horizontal link line HLIA4 in first dummy connection holes DCTH1 in the first planarization layer 331. The first to third vertical metal patterns (VLIA1_DC to VLIA3_DC) may be configured to overlap with the fourth horizontal link line HLIA4 in first dummy connection holes DCTH1 in the first planarization layer 331.

Referring to FIG. 9, the fourth vertical link line VLIA4 may be connected to the fourth horizontal link line HLIA4 through a third connection hole CTH3 in the first planarization layer 331.

Referring to FIG. 9, the fifth and sixth vertical link lines (VLIA5 and VLIA6) may be configured to overlap with the fourth horizontal metal pattern HLIA4_DC in second dummy connection holes DCTH2 in the first planarization layer 331.

Referring to FIG. 9, a second planarization layer 332 (e.g., the second planarization layer 332 of GIG. 3) may be disposed on the first to sixth data lines (DL1 to DL6), the first to third vertical metal patterns (VLIA1_DC to VLIA3_DC), and the fourth to sixth vertical link line (VLIA4 to VLIA6).

Hereinafter, the display panel 110 having the bezel reduction data link structure according to aspects of the present disclosure is described in more detail with reference to FIG. 8.

Referring to FIG. 8, in one or more aspects, the display panel 110 may include the substrate 111 including the active area AA in which a plurality of substrates SP are disposed and the non-active area NA located outside of the active area AA and including the pad area PA, the first data pad DP1 disposed in the pad area PA, and the first data line DL1 disposed in the active area AA, extending in the column direction, and allowing a data voltage to be applied.

In one or more aspects, the display panel 110, which has the bezel reduction data link structure, may include the first horizontal link line HLIA1 and the first vertical link line VLIA1 electrically connected to the first data line DL1.

The first horizontal link line HLIA1 may be electrically connected to the first data line DL1 and extend in the row direction, and the first vertical link line VLIA1 may electrically interconnect the first horizontal link line HLIA1 and the first data pad DP1 and extend in the column direction.

The first horizontal link line HLIA1 may be disposed in the active area AA allowing an image to be displayed, and all or at least part of the first vertical link line VLIA1 may be placed in the active area AA. According to these configurations, the bezel size needed for allowing the application of the data link structure can be reduced.

The first data line DL1 may be disposed in the second metal layer ML2. The first horizontal link line HLIA1 may be disposed in the first metal layer ML1, and the first vertical link line VLIA1 may be disposed in the second metal layer ML2 different from the first metal layer ML1.

According to these configurations, horizontal lines extending in the horizontal direction (row direction) may be disposed in the first metal layer ML1, and vertical lines extending in the vertical direction (column direction) may be disposed in the second metal layer ML2.

In one or more aspects, the second metal layer ML2 may be located higher from the substrate 111 than the first metal layer ML1. For example, the first metal layer ML1 may be a first source-drain metal layer, and the second metal layer ML2 may be a second source-drain metal layer.

In one or more aspects, in conjunction with the bezel reduction data link structure, the display panel 110 may further include the first horizontal metal patterns HLIA1_DC spaced apart from the first horizontal link line HLIA1 and extending in the row direction, and the first vertical metal pattern VLIA1_DC spaced apart from the first vertical link line VLIA1 and extending in the column direction and.

The first horizontal metal patterns HLIA1_DC may be disposed in the first metal layer ML1, and the first vertical metal pattern VLIA1_DC may be disposed in the second metal layer ML2.

As the first horizontal metal patterns HLIA1_DC may be disposed in the same shape and arrangement as the first horizontal link line HLIA1, and the first vertical metal pattern VLIA1_DC may be disposed in the same shape and arrangement as the first vertical link line VLIA1, the display panel 110 can provide advantages of reducing display artifacts such as image abnormalities, image display defects, and the like.

In one or more aspects, the first horizontal metal pattern HLIA1_DC and the first vertical metal pattern VLIA1_DC may be electrically floating.

In one or more aspects, the low power supply voltage VSS, which is the second common driving voltage (see FIG. 2), may be applied to the first horizontal metal patterns HLIA1_DC and the first vertical metal pattern VLIA1_DC.

Paths in which the low power supply voltage VSS is transmitted may be configured in a mesh pattern through the first horizontal metal patterns HLIA1_DC and the first vertical metal pattern VLIA1_DC, and thereby, the transmission characteristics of the low power supply voltage VSS can be significantly improved.

In one or more aspects, as described above, the display panel 110 may include a low power supply line VSSL (e.g., the low power supply line VSSL in FIG. 2) for delivering the low power supply voltage VSS corresponding to a common driving voltage to a plurality of subpixels SP.

The low power supply voltage line VSSL may be electrically connected to the first horizontal metal patterns HLIA1_DC and the first vertical metal pattern VLIA1_DC.

In one or more aspects, each of the plurality of subpixels SP may include a light emitting element ED including a pixel electrode PE, an intermediate layer EL, and a common electrode CE, and the first horizontal metal patterns HLIA1_DC and the first vertical metal pattern VLIA1_DC may be electrically connected to the common electrode CE to which the low power supply voltage VSS is applied.

In one or more aspects, the low power supply voltage VSS, which is a signal having a constant voltage level, may be applied to the first horizontal metal patterns HLIA1_DC and the first vertical metal pattern VLIA1_DC.

In one or more aspects, as described above, to provide a data link structure for the second data line DL2, the display panel 110 may include the second horizontal link line HLIA2 electrically connected to the second data line DL2 and the second vertical link line VLIA2.

The second horizontal link line HLIA2 may be electrically connected to the second data line DL2 and extend in the row direction, and the second vertical link line VLIA2 may electrically interconnect the second horizontal link line HLIA2 and the second data pad DP2 and extend in the column direction.

The second horizontal link line HLIA2 may be disposed in the active area AA allowing an image to be displayed, and all or at least part of the second vertical link line VLIA2 may be placed in the active area AA. According to these configurations, the bezel size needed for allowing the application of the data link structure can be reduced.

The second horizontal link line HLIA2 may be disposed in the first metal layer ML1, and the second vertical link line VLIA2 may be disposed in the second metal layer ML2 different from the first metal layer ML1.

In one or more aspects, in conjunction with the bezel reduction data link structure, the display panel 110 may further include the second horizontal metal patterns HLIA2_DC spaced apart from the second horizontal link line HLIA2 and extending in the row direction, and the second vertical metal pattern VLIA2_DC spaced apart from the second vertical link line VLIA2 and extending in the column direction and.

The second horizontal metal patterns HLIA2_DC may be disposed in the first metal layer ML1, and the second vertical metal pattern VLIA2_DC may be disposed in the second metal layer ML2.

As the second horizontal metal patterns (HLIA2_DC) may be disposed in the same shape and arrangement as the second horizontal link line HLIA2, and the second vertical metal pattern VLIA2_DC may be disposed in the same shape and arrangement as the second vertical link line VLIA2, the display panel 110 can provide advantages of reducing display artifacts such as image abnormalities, image display defects, and the like.

In one or more aspects, the second horizontal metal patterns HLIA2_DC and the second vertical metal pattern VLIA2_DC may be electrically floating.

In one or more aspects, the low power supply voltage VSS, which is the second common driving voltage, may be applied to the second horizontal metal patterns HLIA2_DC and the second vertical metal pattern VLIA2_DC.

Paths in which the low power supply voltage VSS is transmitted may be configured in a mesh pattern through the second horizontal metal patterns HLIA2_DC and the second vertical metal pattern VLIA2_DC, and thereby, the transmission characteristics of the low power supply voltage VSS can be significantly improved.

In one or more aspects, as described above, the display panel 110 may include a low power supply line VSSL (e.g., the low power supply line VSSL in FIG. 2) for delivering the low power supply voltage VSS corresponding to a common driving voltage to a plurality of subpixels SP.

The low power supply voltage line VSSL may be electrically connected to the second horizontal metal patterns HLIA2_DC and the second vertical metal pattern VLIA2_DC.

In one or more aspects, each of the plurality of subpixels SP may include a light emitting element ED including a pixel electrode PE, an intermediate layer EL, and a common electrode CE, and the second horizontal metal patterns HLIA2_DC and the second vertical metal pattern VLIA2_DC may be electrically connected to the common electrode CE to which the low power supply voltage VSS is applied.

In one or more aspects, the low power supply voltage VSS, which is a signal having a constant voltage level, may be applied to the second horizontal metal patterns HLIA2_DC and the second vertical metal pattern VLIA2_DC.

Hereinafter, the application of the first metal layer ML1 and the second metal layer ML2 in the display panel 110 is briefly described with reference to FIG. 3.

In the display panel 110, horizontal lines extending in the horizontal direction (row direction) may be disposed in the first metal layer ML1, and vertical lines extending in the vertical direction (column direction) may be disposed in the second metal layer ML2.

Referring to FIG. 3, each of a plurality of subpixels SP may include a light emitting element ED and two or more transistors (TFT1 and TFT2). The two or more transistors (TFT1 and TFT2) may include source electrodes (E1b and E2b) and drain electrodes (E1c and E2c).

The source electrodes (E1b and E2b) and the drain electrodes (E1c and E2c) may include a first metal included in the first horizontal link line HLIA1 and the first horizontal metal patterns HLIA1_DC. For example, the first metal may be a metal forming a first metal layer ML1. The first horizontal link line HLIA1 and the first horizontal metal patterns HLIA1_DC may be included in a horizontal line.

Referring to FIG. 3, the light emitting element ED may include a pixel electrode PE, an intermediate layer EL, and a common electrode CE, and the relay electrode RE may electrically connect the source electrode E1b or drain electrode E1c of a first transistor TFT1 among two or more transistors (TFT1 and TFT2) to the pixel electrode PE.

The relay electrode RE may include a second metal included in the first vertical link line VLIA1 and the first vertical metal pattern VLIA1_DC. For example, the second metal may be a metal forming a second metal layer ML2. The first vertical link line VLIA) and the first vertical metal pattern VLIA1_DC may be included in a vertical line.

The first data line DL1, which is a type of vertical line, may also be disposed in the second metal layer ML2.

The example embodiments described herein are briefly described as follows.

According to the example embodiments described herein, a display apparatus can be provided that includes a substrate in which an active area including a plurality of subpixels and a non-active area located outside of the active area and comprising a pad area are defined, at least one pad disposed in the pad area, at least one data line disposed in the active area and extending in a column direction, at least one horizontal link line electrically connected to the at least one data line and extending in a row direction, at least one vertical link line electrically interconnecting the at least one horizontal link line and the at least one pad and extending in the column direction, at least one horizontal metal pattern spaced apart from the at least one horizontal link line and extending in the row direction, at least one vertical metal pattern spaced apart from the at least one vertical link line and extending in the column direction, a first area including at least one first connection hole through which the at least one data line and the at least one horizontal metal pattern are electrically interconnected, a second area including at least on first dummy connection hole in an area in which each of the at least one data line and the at least one vertical metal pattern overlaps with the at least one horizontal link line, and a third area including at least one second dummy connection hole in an area in which the at least one vertical link line and the at least one horizontal metal pattern overlap with each other.

In one or more aspects, the at least one horizontal link line and the at least one horizontal metal pattern may be disposed in a first metal layer.

In one or more aspects, the at least one vertical link line and the at least one vertical metal pattern may be disposed in a second metal layer different from the first metal layer.

In one or more aspects, the at least one data line may be disposed in the second metal layer.

In one or more aspects, the second metal layer may be disposed higher from the substrate than the first metal layer.

In one or more aspects, the display apparatus may further include at least one second connection hole through which the at least one data line and the at least one horizontal link line are electrically interconnected, and at least one third connection hole through which the at least one horizontal link line and the at least one vertical link line are electrically interconnected. The at least one second connection hole may be disposed in a first inclined direction relative to a horizontal or vertical direction, and the at least one third connection hole may be disposed in a second inclined direction different from the first inclined direction.

In one or more aspects, a boundary between the first area and the second area may be formed in the first inclined direction in which the at least one second connection hole is disposed, and a boundary between the second area and the third area may be formed in the second inclined direction in which the at least one third connection hole is disposed.

In one or more aspects, the display apparatus may further include a planarization layer disposed on the at least one horizontal link line and the at least one horizontal metal pattern, and the at least one first connection hole, the at least one second connection hole, the at least one third connection hole, the at least on first dummy connection hole, and the at least one second dummy connection hole may be disposed in the planarization layer.

In one or more aspects, the display apparatus may further include a low voltage line for supplying a low power supply voltage corresponding to a common driving voltage to the plurality of subpixels, and the low voltage line may be electrically connected to the at least one horizontal metal pattern and the at least one vertical metal pattern.

In one or more aspects, each of the plurality of subpixels may include a light emitting element including a pixel electrode, an intermediate layer, and a common electrode, and the at least one horizontal metal pattern and the at least one vertical metal pattern may be electrically connected to the common electrode.

In one or more aspects, the display apparatus may further include at least one first open area in which the at least one horizontal link line and the at least one horizontal metal pattern are spaced apart, and at least one second open area in which the at least one vertical link line and the at least one vertical metal pattern are spaced apart.

In one or more aspects, the at least one horizontal link line may be disposed in the active area, and all or at least part of the at least one vertical link line may be disposed in the active area.

In one or more aspects, each of the plurality of subpixels may include a light emitting element and two or more transistors, and the light emitting element may include a pixel electrode, an intermediate layer, and a common electrode. A source electrode or drain electrode of each of the two or more transistors may include a first metal included in at least one of the at least one horizontal link line and the at least one horizontal metal pattern.

In one or more aspects, the display apparatus may further include a relay electrode for electrically connecting the pixel electrode with the source or drain electrode of one transistor among the two or more transistors, and the relay electrode may include a second metal included in at least one of the at least one vertical link line and the at least one vertical metal pattern.

According to the aspects described herein, a display apparatus may be provided with a data link structure capable of reducing the bezel of a display panel.

According to the aspects described herein, a display apparatus may be provided that has a bezel reduction data link structure capable of improving image quality.

According to the aspects described herein, a display apparatus may be provided that has a bezel reduction data link structure capable of improving the performance of transmitting a common driving voltage.

According to the aspects described herein, a display apparatus may be provided that has a bezel reduction data link structure capable of correcting display artifacts such as some image display defects perceived as patterns.

According to the aspects described herein, a display apparatus and/or a display panel may be provided that has a reduced weight by reducing the bezel of the display panel using an improved data link structure.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. The above description and the accompanying drawings provide examples of the technical features of the present disclosure for illustrative purposes only. That is, the disclosed embodiments are intended to illustrate the scope of the technical features of the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate in which an active area including a plurality of subpixels and a non-active area located outside of the active area and comprising a pad area are defined;
at least one pad disposed in the pad area;
at least one data line disposed in the active area and extending in a column direction;
at least one horizontal link line electrically connected to the at least one data line and extending in a row direction;
at least one vertical link line electrically interconnecting the at least one horizontal link line and the at least one pad and extending in the column direction;
at least one horizontal metal pattern spaced apart from the at least one horizontal link line and extending in the row direction;
at least one vertical metal pattern spaced apart from the at least one vertical link line and extending in the column direction;
a first area comprising at least one first connection hole through which the at least one data line and the at least one horizontal metal pattern are electrically connected;
a second area comprising at least on first dummy connection hole in an area in which the at least one data line and the at least one vertical metal pattern overlaps with the at least one horizontal link line; and
a third area comprising at least one second dummy connection hole in an area in which the at least one vertical link line and the at least one horizontal metal pattern overlap with each other.

2. The display apparatus of claim 1, wherein the at least one horizontal link line and the at least one horizontal metal pattern are disposed in a first metal layer, and the at least one vertical link line and the at least one vertical metal pattern are disposed in a second metal layer different from the first metal layer.

3. The display apparatus of claim 2, wherein the at least one data line is disposed in the second metal layer.

4. The display apparatus of claim 2, wherein the second metal layer is disposed higher from the substrate than the first metal layer.

5. The display apparatus of claim 4, further comprising a planarization layer disposed between the first metal layer and the second metal layer,
wherein the at least one first connection hole, the at least one first dummy connection hole, and the at least one second dummy connection hole are disposed in the planarization layer.

6. The display apparatus of claim 1, further comprising:
at least one second connection hole through which the at least one data line and the at least one horizontal link line are electrically connected; and
at least one third connection hole through which the at least one horizontal link line and the at least one vertical link line are electrically connected,
wherein the at least one second connection hole is disposed in a first inclined direction relative to a horizontal or vertical direction, and the at least one third connection hole is disposed in a second inclined direction different from the first inclined direction.

7. The display apparatus of claim 6, wherein a boundary between the first area and the second area is formed in the first inclined direction in which the at least one second connection hole is disposed, and a boundary between the second area and the third area is formed in the second inclined direction in which the at least one third connection hole is disposed.

8. The display apparatus of claim 6, further comprising a planarization layer disposed on the at least one horizontal link line and the at least one horizontal metal pattern,
wherein the at least one first connection hole, the at least one second connection hole, the at least one third connection hole, the at least on first dummy connection hole, and the at least one second dummy connection hole are disposed in the planarization layer.

9. The display apparatus of claim 1, further comprising a low voltage line for supplying a low power supply voltage corresponding to a common driving voltage to the plurality of subpixels,
wherein the low voltage line is electrically connected to the at least one horizontal metal pattern and the at least one vertical metal pattern.

10. The display apparatus of claim 1, wherein each of the plurality of subpixels comprises a light emitting element comprising a pixel electrode, an intermediate layer, and a common electrode, and
wherein the at least one horizontal metal pattern and the at least one vertical metal pattern are electrically connected to the common electrode.

11. The display apparatus of claim 1, further comprising:
at least one first open area in which the at least one horizontal link line and the at least one horizontal metal pattern are spaced apart; and
at least one second open area in which the at least one vertical link line and the at least one vertical metal pattern are spaced apart.

12. The display apparatus of claim 1, wherein the at least one horizontal link line is disposed in the active area, and all or at least part of the at least one vertical link line is disposed in the active area.

13. The display apparatus of claim 1, wherein each of the plurality of subpixels comprises a light emitting element and two or more transistors,
wherein the light emitting element comprises a pixel electrode, an intermediate layer, and a common electrode, and
wherein a source electrode or drain electrode of each of the two or more transistors comprises a first metal included in at least one of the at least one horizontal link line and the at least one horizontal metal pattern.

14. The display apparatus of claim 13, further comprising: a relay electrode for electrically connecting the pixel electrode with the source or drain electrode of one transistor among the two or more transistors,
wherein the relay electrode comprises a second metal included in at least one of the at least one vertical link line and the at least one vertical metal pattern.

15. A display apparatus comprising:
a substrate in which an active area including a plurality of subpixels and a non-active area located outside of the active area and comprising a pad area are defined;
a plurality of pads disposed in the pad area;
a plurality of data lines disposed in the active area and extending in a first direction;
a plurality of horizontal link lines extending in a second direction perpendicular to the first direction; and
a plurality of vertical link lines extending in the first direction,
wherein at least one of the plurality of vertical link lines include a first end electrically connected to a corresponding pad among the plurality of pads, and a second end connected to a first end of a corresponding horizontal link line among the plurality of horizontal link lines via a second connection hole, and
wherein a second end of the corresponding horizontal link line is connected to a corresponding data line among the plurality of data lines via a third connection hole.

16. The display apparatus of claim 15, wherein at least one of the plurality of vertical link lines include a first end electrically connected to a corresponding pad among the plurality of pads, and a second end connected to a corresponding data line among the plurality of data lines among the plurality of horizontal link lines via a first connection hole.
